(19) United States
(12) Patent Application Publication
(10) Pub. No.: US 2026/0312723 A1
(43) Pub. Date: Oct. 8, 2026

(54) LOW GATE-COUNT HARDWARE ARCHITECTURE FOR LIST-DECODING OF POLAR CODE

(71) Applicant: Samsung Electronics Co., Ltd., Suwon-si (KR)

(72) Inventors: Amit BERMAN, Tel-Aviv (IL); Yoel BOKOBZA, Tel-Aviv (IL); Ariel DOUBCHAK, Tel-Aviv (IL); Dikla SHAPIRO, Tel-Aviv (IL)

(73) Assignee: Samsung Electronics Co., Ltd., Suwon-si (KR)

(21) Appl. No.: 19/093,792

(22) Filed: Mar. 28, 2025

(51) Int. Cl. H04L 1/00

(52) U.S. Cl. CPC H04L 1/0057; H04L 1/0045

(57) ABSTRACT

A decoder includes a memory and processor configured to cause the decoder to receive a polar encoded codeword including frozen bits having arbitrary values, and generate a pruned decoding list tree by collapsing special subtrees based on a frozen-qualifiers vector defining values and locations of the frozen bits having arbitrary values. The decoder performs soft calculations of different layers of the pruned tree using one or more modules. The results of the soft calculations are output as lists. The decoder calculates hypotheses and costs for each of K best path options included in each of L lists according to a size and a type of tree, determines the best path out of L*K best path options based on the hypotheses and costs, calculates hard decisions for the K best path options, and outputs one of the hard decisions as a decoded codeword.

### TECHNICAL FIELD

This application relates generally to decoder architectures, and more specifically to decoder architectures for list-decoding of polar codes.

### BACKGROUND

Polar codes are a type of linear block error-correcting codes that rely on channel polarization, in which a noisy communication channel is split into highly reliable and highly unreliable virtual channels. Data bits are assigned to the reliable channels. Non-data frozen bits, which have a fixed value of zero are assigned to the unreliable channels. Locations of the frozen bits are known ahead of time by the decoder, which may use that knowledge, in the decoding process. Decoders used to decode polar encoded codewords include successive cancellation (SC) decoders, successive cancellation list (SCL) decoders, and simplified successive cancellation list (SSCL) decoders.

### SUMMARY

The scope of protection sought for various example embodiments is set out by the independent claims. The example embodiments and/or features, if any, described in this specification that do not fall under the scope of the independent claims are to be interpreted as examples useful for understanding various embodiments.

Example embodiments disclosed herein include a super-fast simplified successive cancellation list (S-FSSCL) decoder for use with a binary symmetric channel. The terms “decoder,” “polar decoder,” and similar terms used herein should be understood to refer to an S-FSSCL decoder, unless otherwise required by context. Various example embodiments of decoder architectures, hardware, firmware, software, and algorithms disclosed herein may be implemented using low-gate count hardware, at least in part due to the introduction of novel special tree structures that may limit the number of nodes for which soft calculations are made. Various example embodiments also reduce decoder hardware complexity as compared to conventional decoders, by limiting the number of paths for which hypotheses and/or hard decisions are calculated. In some example embodiments, a novel exhaustive search method may be used for small trees or subtrees, e.g., subtrees limited to 8 leaf nodes. This novel exhaustive search method for small trees may allow a decoder according to various example embodiments to forego calculating log likelihood ratios (LLRs) in lower levels of the tree. Because the LLRs of lower levels of a tree require more bits to represent than the LLRs of upper and middle levels, the number of bits needed to represent LLRs may be decreased.

In addition to improvements in decoder hardware complexity achieved by reducing gate count, improved decoder functionality may be provided by allowing the use of arbitrary frozen bit values, so that frozen values need not be limited to having a value of zero. Instead, in some example embodiments that support arbitrary frozen bit values, all frozen bits in a codeword being decoded may have a value of one, all frozen bits in the codeword may have a value of zero, or some frozen bits may have a value of one while other frozen bits in the same codeword have a value of zero. Additional functionality may be provided by various example embodiments herein through the support of dynamic frozen bits, which have a value that depends on other bits within the codeword.

As used herein, the terms “frozen bits,” “frozens,” and derivatives thereof are used interchangeably to refer to specific bits within a codeword that have been set to a predetermined value. Conventionally all frozens in a codeword have the same value, which is typically 0. Frozens do not change during the encoding process, so the value of frozen bits may be known by the decoder.

In various example embodiments, a decoder includes a memory storing instructions, and a processor coupled to the memory, the processor configured to execute the instructions to cause the decoder to receive a polar encoded codeword including frozen bits having arbitrary values, generate a pruned decoding list tree by collapsing special subtrees identified based on a frozen-qualifiers vector defining values and locations of the frozen bits having arbitrary values within the polar encoded codeword, perform first soft calculations for nodes in upper layers of the pruned decoding list tree, the first soft calculations generating first outputs including soft values for nodes in the upper layers of the pruned decoding list tree, perform mid-layer soft calculations for nodes in mid layers of the pruned decoding list tree, the mid-layer soft calculations generating second outputs including a plurality of lists of path metrics for each root node of a subtree of the pruned decoding list tree, each path metric associated with a path from the root node of the subtree to a terminal node of the subtree, the plurality of lists including L lists, each of the L lists including K best path options, the L lists cumulatively including L*K best path options, calculate hypotheses and costs for each of K best path options included in each of the L lists according to a size and a type of tree, the hypotheses representing decisions for potential decode continuation, determine the best path out of the L*K best path options based on the hypotheses and costs of each of the K best path options included in each of the L lists, calculate hard decisions for the K best path options included in each of the L lists, and output one of the hard decisions as a decoded codeword.

In some such example embodiments, at least one of the special subtrees includes at least one of a double parity check (DPC) tree or a double single-parity-check (DSPC) tree, and the decoder is further caused to decode at least one of the DPC tree or the DSPC tree by extracting a given number of best candidates from one or more tables based on a set of input conditions related to values of frozen vectors included in the DPC tree or the DSPC tree.

In other example embodiments, at least one of the special subtrees includes an exhaustive search tree of size 8, and the decoder is further caused to generate vectors for each possible codeword for the exhaustive search tree; calculate a path metric for each codeword at the root node of the exhaustive search tree; and select K best options out of L possible codewords as the best K codewords for the exhaustive search tree, wherein the K best options have the K best path metrics.

In yet other example embodiments, the frozen-qualifiers vector defines at least one of the frozen bits as a dynamic frozen bit having a dynamic value dependent upon one or more information bits. In some such example embodiments, at least one of the special subtrees includes a dynamic frozen bit, and the processor is configured to execute the instructions to cause the decoder to divide the at least one of the special subtrees into smaller subtrees until the one or more information bits on which the value of the dynamic frozen bit depends are not included in the same subtree as the dynamic frozen bit.

In further example embodiments, the decoder is further caused to support parallel decoding of a variable number of words with a variable number of lists. The decoder may also or alternatively be further caused to concurrently perform first soft calculations for each of three upper layers of the pruned decoding list tree and/or concurrently perform mid-layer soft calculations for a plurality of subtrees of the pruned decoding list.

Other example embodiments include a method including receiving a polar encoded codeword including frozen bits having arbitrary values; generating a pruned decoding list tree by collapsing special subtrees identified based on a frozen-qualifiers vector defining values and locations of the frozen bits having arbitrary values within the polar encoded codeword; performing first soft calculations for nodes in upper layers of the pruned decoding list tree, the soft calculations generating first outputs including soft values for nodes in the upper layers of the pruned decoding list tree; performing mid-layer soft calculations for nodes in mid layers of the pruned decoding list tree, the mid-layer soft calculations generating second outputs including a plurality of lists of path metrics for each root node of a subtree of the pruned decoding list tree, each path metric associated with a path from the root node of the subtree to a terminal node of the subtree, the plurality of lists including L lists, each of the L lists including K best path options, the L lists cumulatively including L*K best path options; calculating hypotheses and costs for each of K best path options included in each of the L lists according to a size and a type of tree, the hypotheses representing decisions for potential decode continuation; determining the best path out of the L*K best path options based on the hypotheses and costs of each of the K best path options included in each of the L lists, calculating hard decisions for the K best path options included in each of the L lists; and outputting one of the hard decisions as a decoded codeword.

In some such example embodiments, at least one of the special subtrees includes at least one of a double parity check (DPC) tree or a double single-parity-check (DSPC) tree, and the method further includes decoding at least one of the DPC tree or the DSPC tree by extracting a given number of best candidates from one or more tables based on a set of input conditions related to values of frozen vectors included in the DPC tree or the DSPC tree.

In other example embodiments, at least one of the special subtrees includes an exhaustive search tree of size 8, and the method further includes generating vectors for each possible codeword for the exhaustive search tree; calculating a path metric for each codeword at the root node of the exhaustive search tree; and selecting K best options out of L possible codewords as the best K codewords for the exhaustive search tree, wherein the K best options have the K best path metrics.

In some example embodiments, the frozen-qualifiers vector defines at least one of the frozen bits as a dynamic frozen bit having a dynamic value dependent upon one or more information bits. In some such example embodiments, at least one of the special subtrees includes a dynamic frozen bit, and the method further includes dividing the special subtree into smaller subtrees until the one or more information bits on which the value of the dynamic frozen bit depends are not included in the same subtree as the dynamic frozen bit.

In further example embodiments, the method includes decoding, in parallel, a variable number of words with a variable number of lists, performing concurrently the first soft calculations for each of three upper layers of the pruned decoding list tree, and/or performing concurrently the mid-layer soft calculations for a plurality of the subtrees of the pruned decoding list.

A decoder according to various example embodiments includes a memory storing instructions, a processor coupled to the memory, the processor configured to execute the instructions to cause the decoder to coordinate operation of a plurality of decoder modules to perform simplified sequential list decoding of a polar encoded codeword including frozen bits having arbitrary values using a controller, perform soft calculations for target nodes using at least one soft calculation module, the soft calculations being performed on a per target node basis for target nodes of a pruned decoding list tree; generate a plurality of lists identifying best paths within each subtree using a subtree decision module, the plurality of lists including L lists, each of the L lists including K best path options, the L lists cumulatively including L*K best path options; select a best list of the L lists using a subtree decision module, the best list including a best path of the L*K best path options; and manage the plurality of lists, including the best list, generated by the subtree decision module using a list management module including the best list.

In some such example embodiments, the decoder is further caused to use the controller to maintain decode state variables using node indexes, and generate a pruned decoding list tree by collapsing special subtrees identified based on a frozen-qualifiers vector defining values and locations of the frozen bits having arbitrary values within the polar encoded codeword.

In other example embodiments, the decoder is further caused to use the at least one soft calculation module to receive first node identifiers from the controller, the polar encoded codeword, and up to L lists including past decisions from the list manager module; perform first soft calculations for nodes identified by the node identifiers, the polar encoded codeword, and the up to L lists, wherein performing the first soft calculations includes using a value of 0.5 for each bit of the polar encoded codeword; and generate first outputs including soft values for nodes in first layers of the pruned decoding list tree.

In one or more example embodiments, the decoder is further caused to use the at least one soft calculation module to receive second node identifiers from the controller and to receive the polar encoded codeword, the second node identifiers identifying a root node of a subtree of the pruned decoding list tree; perform second soft calculations for nodes identified by the second node identifiers; and generate second outputs including lists of path metrics for each of the second nodes, each path metric associated with a path from the root node of the subtree to a terminal node of the subtree.

In yet other example embodiments, the decoder is further caused to use the subtree decision module to calculate hypotheses and costs for each of K best path options included in each of the L lists according to a size and a type of tree, the hypotheses representing decisions for potential decode continuation; determine the best path of the L*K best path options based on the hypotheses and costs of each of the K best path options included in each of the L lists; calculate hard decisions for the K best path options included in each of the L lists; and output the hard decision to the list management module.

In various example embodiments, a decoder includes a memory storing instructions, and a processor coupled to the memory, the processor configured to execute the instructions to receive a polar encoded codeword including frozen bits having arbitrary values, generate a pruned decoding list tree by collapsing special subtrees identified based on a frozen-qualifiers vector defining values and locations of the frozen bits having arbitrary values within the polar encoded codeword, perform first soft calculations for nodes in upper layers of the pruned decoding list tree, the first soft calculations generating first outputs including soft values for nodes in the upper layers of the pruned decoding list tree, perform mid-layer soft calculations for nodes in mid layers of the pruned decoding list tree, the mid-layer soft calculations generating second outputs including a plurality of lists of path metrics for each root node of a subtree of the pruned decoding list tree, each path metric associated with a path from the root node of the subtree to a terminal node of the subtree, the plurality of lists including L lists, each of the L lists including K best path options, the L lists cumulatively including L×K best path options, calculate hypotheses and costs for each of K best path options included in each of the L lists according to a size and a type of the pruned decoding list tree, the hypotheses representing decisions for potential decode continuation, determine the best path out of the L×K best path options based on the hypotheses and costs of each of the K best path options included in each of the L lists, and a hard decision function, and output a decoded codeword based on the best path.

Any or all of the above example embodiments, and other example embodiments disclosed herein, may be used in various combinations to provide decoding of polar encoded codewords.

### BRIEF DESCRIPTION OF THE DRAWINGS

Example embodiments will become more fully understood from the detailed description given herein below and the accompanying drawings, wherein like elements are represented by like reference numerals. The example embodiments are given by way of illustration only, and thus are not limiting of this disclosure.

FIG. 1 is diagram of a rate-0 tree with arbitrary frozen bit values, in accordance with various example embodiments.

FIG. 2 is diagram of a repetition (REP) tree with arbitrary frozen bit values, in accordance with various example embodiments.

FIG. 3 is diagram of a single parity check (SPC) tree with arbitrary frozen bit values, where the parity constraint does not hold, in accordance with various example embodiments.

FIG. 4 is diagram of a double parity check (DPC) tree of size 8 with arbitrary frozen bit values, in accordance with various example embodiments.

FIG. 5 is diagram of a double single-parity check (DSPC) tree of size 8 with arbitrary frozen bit values, in accordance with various example embodiments.

FIG. 6 is diagram of a rate-0 SPC tree of size 8 with arbitrary frozen bit values, in accordance with various example embodiments.

FIG. 7 is diagram of a DSPC tree with a leaf including a frozen bit having a dynamic value, in accordance with various example embodiments.

FIG. 8 is diagram of a simplified pruned tree with variable likelihood log ratio widths, in accordance with various example embodiments.

FIG. 9 is a block diagram of decoder hardware top blocks, in accordance with various example embodiments.

FIG. 10 is a tree diagram illustrating node indexing, in accordance with various example embodiments.

FIG. 11 is a block diagram illustrating using a node as a state descriptor, in accordance with various example embodiments.

FIG. 12 is a block diagram illustrating next subtree scanning in a start condition, in accordance with various example embodiments.

FIG. 13 is a block diagram illustrating next subtree scanning in an advance state, in accordance with various example embodiments.

FIG. 14 is a tree diagram illustrating first (upper) layers of a tree, in accordance with various example embodiments.

FIG. 15 is a tree diagram illustrating first (upper) layers calculation paths, in accordance with various example embodiments.

FIG. 16 is a tree diagram illustrating mid-layers calculation paths, in accordance with various example embodiments.

FIG. 17 is a block diagram illustrating a mid-layers shared output format, in accordance with various example embodiments.

FIG. 18 is a block diagram illustrating a sub-tree decision block/module, in accordance with various example embodiments.

FIG. 19 is a block diagram illustrating a list manager, in accordance with various example embodiments.

FIGS. 20-21 are diagrams illustrating list structures at various stages of a decoding process, in accordance with various example embodiments.

FIG. 22 is a block diagram of a processing device, in accordance with various example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. The use of similar or identical reference numbers in the various drawings is intended to indicate the presence of a similar or identical element or feature.

### DETAILED DESCRIPTION

Various example embodiments will now be described more fully with reference to the accompanying drawings in which some example embodiments are shown.

Detailed illustrative embodiments are disclosed herein. However, specific structural and functional details disclosed herein are merely representative for purposes of describing example embodiments. It should be understood that there is no intent to limit example embodiments to the particular forms disclosed. On the contrary, example embodiments are to cover all modifications, equivalents, and alternatives falling within the scope of this disclosure. Like numbers may refer to like elements throughout the description of the figures. One or more example embodiments described herein may be combined.

Successive cancellation (SC) decoders use a technique in which bits of a codeword are represented as a binary tree structure. Each bit in the tree structure is decoded one at a time, in a specific order, with each decoded bit influencing the decoding of subsequent bits. An SC decoder may choose particular tree nodes to be included in the decoding path (or simply referred to as “path”) during the decoding process, but once a node is included in part of the path, the node becomes a part of the decoding path.

Successive cancellation list (SCL) decoders also represent codewords as a binary tree structure, but SCL decoders maintain a list of multiple potential decoding paths through the tree structure, allowing selection of one or more calculated values for each bit, where the calculated values may vary depending on the chosen path. The path chosen to provide the calculated value may be selected based on a path metric (PM) associated with each path. The path metric is often a logarithmic likelihood ratio (LLR).

Simplified successive cancellation list (SSCL) decoders, like SCL decoders, maintain a list of potential paths to use for determining the most likely value of a bit in a codeword, but also use list splitting at the root level of specific trees/subtrees, and directly compute PMs from the LLRs at the root node. This approach may eliminate the necessity to traverse the entire tree, but list decisions are still made sequentially, resulting in increased latency, particularly when dealing with large list sizes.

Example embodiments disclosed herein provide improved decoding latency over conventional SSCL decoders, with reasonable polar performance in terms of frame error rate (FER) at high throughput when the decoder is in hard decision (HD) mode. In HD mode, the channel is a binary-symmetric channel (BSC). To achieve the improvements over conventional SSCL decoders, various example embodiments calculate decoded values of a codeword using new special tree structures, and perform bit decoding of codewords with arbitrary and/or dynamic frozen bit values.

Some example embodiments extend the use of conventional “special” sub-trees, e.g., rate-0, repetition (REP), rate-1, and SPC trees, for use with arbitrary frozen bit values. New special subtrees include double parity check (DPC) trees of size 8, double single-parity check (DSPC) trees of size 8, and rate-0 SPC trees of size 8. For example, the special subtrees according to various example embodiments may include at least one of a DPC tree and a DSPC tree.

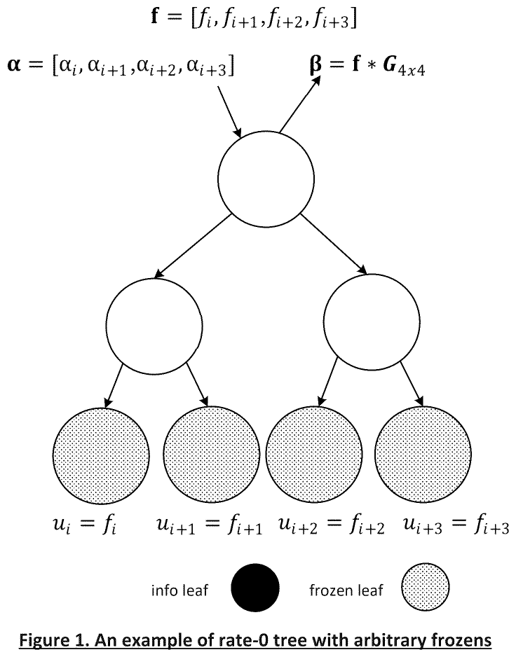

Referring now to FIG. 1, a rate-0 tree with arbitrary frozen bit values will be discussed in accordance with various example embodiments.

Conventionally, the value of frozen bits in a polar encoded codeword are assumed to be zero (0). However, scenarios exist where this assumption is not guaranteed. To allow proper, efficient operation of a decoder in such cases, various example embodiments generalize conventional, simplified decoding algorithms to support arbitrary frozen bits values.

In various example embodiments, the path metric (PM) for any subtree may be calculated as follows:

PM=Σ_{j∈Γ}|αⱼ|,

where Γ={i|h(αᵢ)≠βᵢ}. Here, αᵢ represents a LLR value of an i-th bit, βᵢ represents a bit value of the i-th bit, and h( ) represents a hard decision function.

Assume a subtree of size m. For rate-0 code, all the leaves are frozens, thereby they are known. If the leaves values u are f (a vector of frozen bit values, or referred to as a frozen vector), then β (hard decision vector)=f·G_{m×m}, where G_{m×m} is the generator matrix of a polar code of size m.

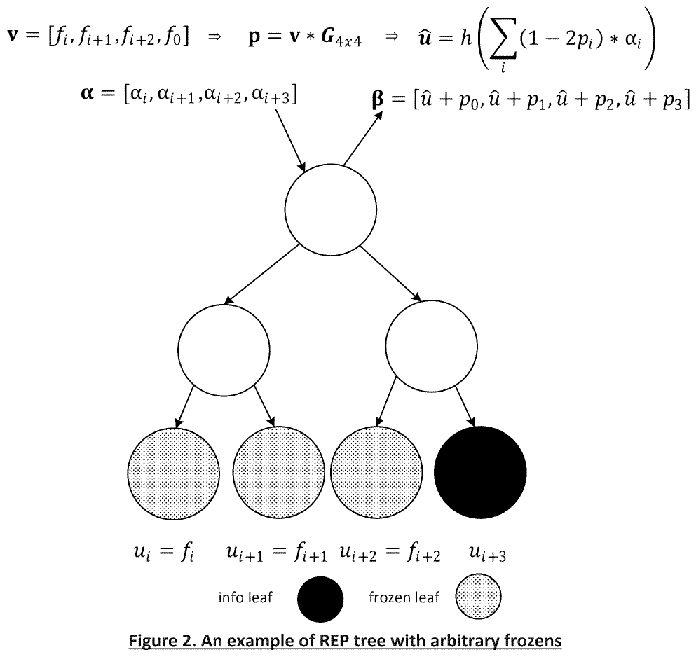

Referring next to FIG. 2, a repetition (REP) tree with arbitrary frozen bit values will be discussed in accordance with various example embodiments. For the root node of an REP subtree, the subtree maximum likelihood (ML) codeword can be calculated as follows:

Let v be a vector of size m such that the rightmost bit is 0, and all the other bits on the left side are the frozen bits of the REP tree. Define p=v·G_{m×m}. Then

$$\hat{μ} = h ( {\sum }_{i = 0}^{m - 1} \text{?} ( 1 - 2 {p}_{i} ) {α}_{i} ) \text{?} ,$$

and β=[û+p₀, û+p₁, . . . , û+pₘ₋₁].

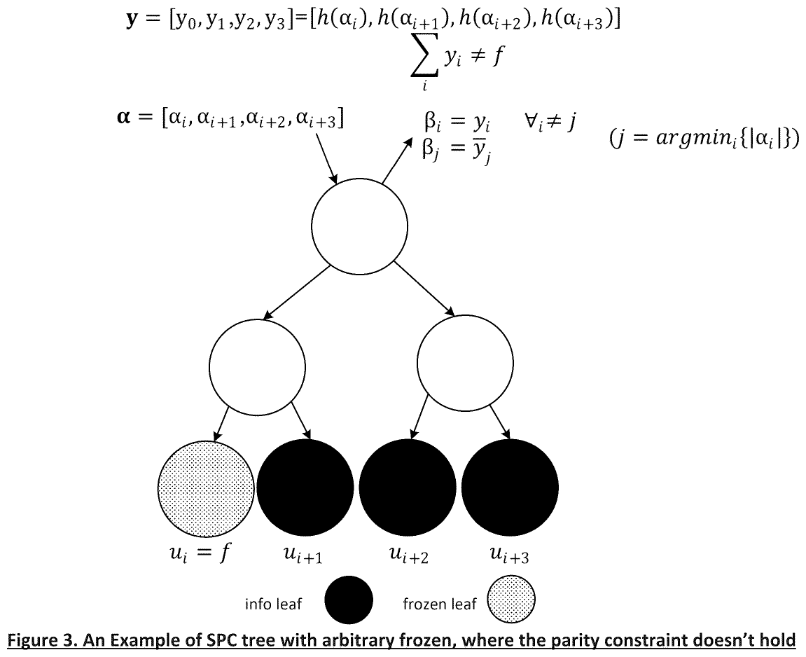

Referring next to FIG. 3, a single parity check (SPC) tree with arbitrary frozen bit values, where the parity constraint does not hold, will be discussed in accordance with various example embodiments.

For SPC nodes at the root of SPC trees, if the frozen bit value is f, then the constraint over β becomes Σᵢ βᵢ=f. Therefore, if y=h(α), satisfies the constraint above, the tree returns β=y. Otherwise, flip the j'th bit of y corresponding to the minimal LLR absolute value j=argminᵢ{|αᵢ|}.

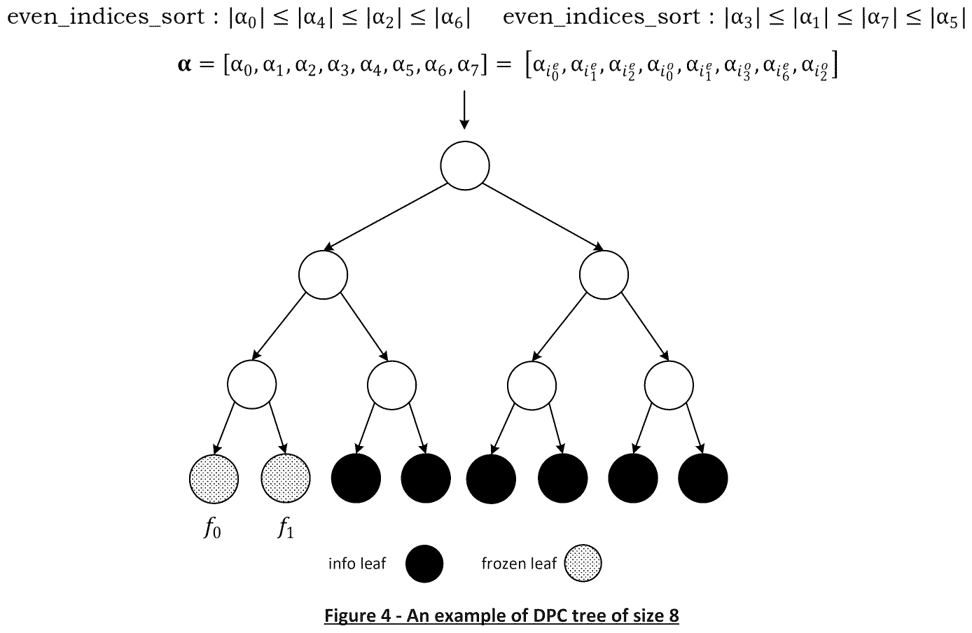

Referring next to FIGS. 4-6, additional special tree types, e.g., a double parity check (DPC) tree of size 8 with arbitrary frozen bit values, a double single-parity check (DSPC) tree of size 8 with arbitrary frozen bit values, and exhaustive search trees of limited size, such as a rate-0 SPC tree of size 8 with arbitrary frozen bit values, are illustrated. Various example embodiments of a super-fast simplified successive cancellation list (S-FSSCL) decoder may use one or more these additional special tree types in addition to conventionally used special trees. S-FSSCL decoders disclosed in various example embodiments may also use the techniques discussed previously for generalizing the conventional special trees, e.g., rate-0, repetition (REP), rate-1, and SPC trees for use with arbitrary frozen bit values.

For various example embodiments of S-FSSCL decoders discussed herein, assume a subtree of size m. Let [symbol] denotes the modulo 2 summation over the hard decision word, i.e.,

$$𝒮 = {\sum }_{i = 0}^{m - 1} {y}_{i} ,$$

where y=h(α). Let αᵢ_{₀}, αᵢ_{₁}, αᵢ_{₂}, αᵢ_{₃} denote the smallest LLRs in terms of absolute value, i.e., |αᵢ_{ⱼ}|≥|αᵢ_{ₖ}| for j>k.

Rate-0 trees (FIG. 1) may be treated as described with respect to FIG. 1, because no splitting is occurred.

REP trees (FIG. 2) are decoded using a list decoder in one or more example embodiments. Because a list decoder considers both possible options of β, the maximum likelihood (ML) candidate need not be calculated for the root node of a REP tree. Therefore, define u⁽⁰⁾=[f₀, f₁, . . . , fₘ₋₂, 0], where f₀, f₁, . . . , fₘ₋₂, are the frozen bit values, and calculate β⁽⁰⁾=u⁽⁰⁾·G_{m×m}, and δ⁽¹⁾=β̅⁽̅⁰̅⁾̅ and the path metric (PM) for each of the two possible options, i.e., 0 and 1.

In the case of SPC nodes (FIG. 3), in at least some example embodiments the best four hard candidates at the tree root (best in terms of lowest PM) may be determined. In one or more example embodiments, the best four hard candidates are determined by determining a set of 5 candidates such that four of them are the best, and using the general value f of the frozen bit of the SPC node.

If [symbol] =f, the best four candidates are as follows:
β⁽⁰⁾=y without bits flipping
β⁽¹⁾=y with flipping bits i₀,i₁
β⁽²⁾=y with flipping bits i₀,i₂
β⁽³⁾=y with flipping bits i₀,i₃, if |αᵢ_{₀}|+|αᵢ_{₃}|≤|αᵢ_{₁}|+|αᵢ_{₂}|; OTHERWISE β⁽³⁾=y with flipping bits i₁,i₂,

If [symbol] ≠f, the best four candidates are:
β⁽⁰⁾=y with flipping bit i₀
β⁽¹⁾=y with flipping bit i₁
β⁽²⁾=y with flipping bit i₂
β⁽³⁾=y with flipping bit i₃, if |αᵢ_{₃}|≤|αᵢ_{₀}|+|αᵢ_{₁}|+|αᵢ_{₂}|; OTHERWISE β⁽³⁾=y with flipping bits i₀, i₁, i₂.

For rate-1 nodes, there are no constraints over the local codeword at the tree root, because there are no frozen bits. In that case, the 4 best candidates are:
β⁽⁰⁾=y without bits flipping
β⁽¹⁾=y with flipping bit i₀
β⁽²⁾=y with flipping bit i₁
β⁽³⁾=y with flipping bit i₂, if |αᵢ_{₂}|≤|αᵢ_{₀}|+|αᵢ_{₁}| OTHERWISE β⁽³⁾=y with flipping bits i₀,i₁.

In FIG. 4, a double parity check (DPC) tree of size 8 with arbitrary frozen bit values will be discussed in accordance with various example embodiments. Rather than successively decoding bits at the root of the tree, various example embodiments herein use parallel list splitting, which is faster than the successive decoding algorithm.

The DPC tree enforces Systematic Polar Code constraint over both the odd bits and the even bits of the codeword. A Systematic Polar Code is a type of polar code where the information bits (data to be transmitted) are explicitly separated and identifiable within the encoded codeword. In some example embodiments, to a size 8 DPC tree with arbitrary frozen bit values, the decoder calculates a PM for each set of 10 hard codewords, and chooses the four best candidates from among those 10 hard codewords (best in terms of PM).

Recall that

$$𝒮 = {\sum }_{i = 0}^{m - 1} {y}_{i} ,$$

where y=h(α). A summation over the odd indices bits is defined as

$${𝒮}_{0} = {\sum }_{i = 0}^{\frac{m}{2} - 1} {y}_{2 i + 1} ,$$

and let

$${α}_{{i}_{0}^{o}} , {α}_{{i}_{1}^{o}} , {α}_{{i}_{2}^{o}} , {α}_{{i}_{3}^{o}} , and {α}_{{i}_{0}^{e}} , {α}_{{i}_{1}^{e}} , {α}_{{i}_{2}^{e}} , {α}_{{i}_{3}^{e}}$$

denote the smallest four sorted LLRs in terms of absolute values in the odd indices (0, 2, . . . ) and in the even indices (1, 3, . . . ), respectively. Further define f₀, and f₁ as the leftmost frozen bit and the second most left frozen bit, respectively.

For each scenario, a table describes a minimal set of 10 candidates that include the four best candidates in terms of PM. Each column in TABLE 1 represents one of the 8 indices of the as described above. If for example, the value of the table in the row corresponding to β^{(j)} and the column corresponding to the index

$${i}_{2}^{e}$$

is 1, then

$${β}_{{i}_{2}^{e}}^{( j )} = {\overline{y}}_{{i}_{2}^{e}} .$$

If the value is 0 then

$${β}_{{i}_{2}^{e}}^{( j )} = {y}_{{i}_{2}^{e}} .$$

As there are two frozen bits, each with an arbitrary binary value, the solution is divided into four cases.

If [symbol] =f₀, and [symbol] ₀=f₁:

TABLE 1

| | ${i}_{0}^{o}$ | ${i}_{1}^{o}$ | ${i}_{2}^{o}$ | ${i}_{3}^{o}$ | ${i}_{0}^{e}$ | ${i}_{1}^{e}$ | ${i}_{2}^{e}$ | ${i}_{3}^{e}$ |
|---|---|---|---|---|---|---|---|---|
| β⁽⁰⁾ | 0 | 0 | 0 | 0 | 0 | 0 | 0 | 0 |
| β⁽¹⁾ | 1 | 1 | 0 | 0 | 0 | 0 | 0 | 0 |
| β⁽²⁾ | 0 | 0 | 0 | 0 | 1 | 1 | 0 | 0 |
| β⁽³⁾ | 1 | 1 | 0 | 0 | 1 | 1 | 0 | 0 |
| β⁽⁴⁾ | 1 | 0 | 1 | 0 | 0 | 0 | 0 | 0 |
| β⁽⁵⁾ | 1 | 0 | 0 | 1 | 0 | 0 | 0 | 0 |
| β⁽⁶⁾ | 0 | 0 | 0 | 1 | 0 | 0 | 0 | 0 |
| β⁽⁷⁾ | 0 | 0 | 0 | 0 | 1 | 0 | 1 | 0 |
| β⁽⁸⁾ | 0 | 0 | 0 | 0 | 0 | 1 | 1 | 0 |
| β⁽⁹⁾ | 0 | 0 | 0 | 0 | 1 | 0 | 0 | 1 |

If [symbol] =f₀, and [symbol] ₀≠f₁:

TABLE 2

| | ${i}_{0}^{o}$ | ${i}_{1}^{o}$ | ${i}_{2}^{o}$ | ${i}_{3}^{o}$ | ${i}_{0}^{e}$ | ${i}_{1}^{e}$ | ${i}_{2}^{e}$ | ${i}_{3}^{e}$ |
|---|---|---|---|---|---|---|---|---|
| β⁽⁰⁾ | 1 | 0 | 0 | 0 | 1 | 0 | 0 | 0 |
| β⁽¹⁾ | 0 | 1 | 0 | 0 | 1 | 0 | 0 | 0 |
| β⁽²⁾ | 1 | 0 | 0 | 0 | 0 | 1 | 0 | 0 |
| β⁽³⁾ | 0 | 1 | 0 | 0 | 0 | 1 | 0 | 0 |
| β⁽⁴⁾ | 0 | 0 | 1 | 0 | 1 | 0 | 0 | 0 |
| β⁽⁵⁾ | 0 | 0 | 0 | 1 | 1 | 0 | 0 | 0 |
| β⁽⁶⁾ | 1 | 0 | 0 | 0 | 0 | 0 | 1 | 0 |
| β⁽⁷⁾ | 1 | 0 | 0 | 0 | 0 | 0 | 0 | 1 |
| β⁽⁸⁾ | 1 | 1 | 1 | 0 | 1 | 0 | 0 | 0 |
| β⁽⁹⁾ | 1 | 0 | 0 | 0 | 1 | 1 | 1 | 0 |

If [symbol] ≠f₀, and [symbol] ₀=f₁:

TABLE 3

| | ${i}_{0}^{o}$ | ${i}_{1}^{o}$ | ${i}_{2}^{o}$ | ${i}_{3}^{o}$ | ${i}_{0}^{e}$ | ${i}_{1}^{e}$ | ${i}_{2}^{e}$ | ${i}_{3}^{e}$ |
|---|---|---|---|---|---|---|---|---|
| β⁽⁰⁾ | 0 | 0 | 0 | 0 | 1 | 0 | 0 | 0 |
| β⁽¹⁾ | 0 | 0 | 0 | 0 | 0 | 1 | 0 | 0 |
| β⁽²⁾ | 1 | 1 | 0 | 0 | 1 | 0 | 0 | 0 |
| β⁽³⁾ | 1 | 1 | 0 | 0 | 0 | 1 | 0 | 0 |
| β⁽⁴⁾ | 0 | 0 | 0 | 0 | 0 | 0 | 1 | 0 |
| β⁽⁵⁾ | 0 | 0 | 0 | 0 | 0 | 0 | 0 | 1 |
| β⁽⁶⁾ | 1 | 0 | 1 | 0 | 1 | 0 | 0 | 0 |
| β⁽⁷⁾ | 0 | 1 | 1 | 0 | 1 | 0 | 0 | 0 |
| β⁽⁸⁾ | 1 | 0 | 0 | 1 | 1 | 0 | 0 | 0 |
| β⁽⁹⁾ | 0 | 0 | 0 | 0 | 1 | 1 | 1 | 0 |

If [symbol] ≠f₀, and [symbol] ₀≠f₁:

TABLE 4

| | ${i}_{0}^{o}$ | ${i}_{1}^{o}$ | ${i}_{2}^{o}$ | ${i}_{3}^{o}$ | ${i}_{0}^{e}$ | ${i}_{1}^{e}$ | ${i}_{2}^{e}$ | ${i}_{3}^{e}$ |
|---|---|---|---|---|---|---|---|---|
| β⁽⁰⁾ | 1 | 0 | 0 | 0 | 0 | 0 | 0 | 0 |
| β⁽¹⁾ | 0 | 1 | 0 | 0 | 0 | 0 | 0 | 0 |
| β⁽²⁾ | 0 | 1 | 0 | 0 | 1 | 1 | 0 | 0 |
| β⁽³⁾ | 1 | 0 | 0 | 0 | 1 | 1 | 0 | 0 |
| β⁽⁴⁾ | 0 | 0 | 1 | 0 | 0 | 0 | 0 | 0 |
| β⁽⁵⁾ | 0 | 0 | 0 | 1 | 0 | 0 | 0 | 0 |
| β⁽⁶⁾ | 1 | 0 | 0 | 0 | 1 | 0 | 1 | 0 |
| β⁽⁷⁾ | 0 | 0 | 0 | 0 | 1 | 1 | 1 | 0 |
| β⁽⁸⁾ | 1 | 0 | 0 | 0 | 1 | 0 | 0 | 1 |
| β⁽⁹⁾ | 1 | 1 | 1 | 0 | 0 | 0 | 0 | 0 |

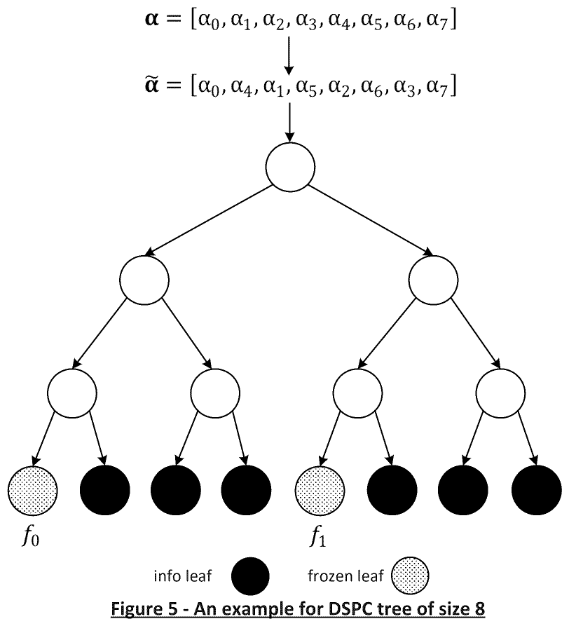

Referring next to FIG. 5, a double single-parity check (DSPC) tree of size 8 with arbitrary frozen bit values will be discussed in accordance with various example embodiments. A DSCP tree is a concatenation of two SPC trees. The condition over the local codewords on the top of the tree are that both the left half and the right half satisfy the SPC constraint. In at least one example embodiment, a DSCP tree may be treated like a DPC tree by applying a permutation over α at the tree root, and then applying the inverse permutation over the final β candidates.

Assume a DSPC tree of size m. Define the permutation

$$perm ( i ) = 2 ( i mod \frac{m}{2} ) + ⌊ \frac{2 i}{m} ⌋ ,$$

and an inverse of the permutation

$${perm}^{- 1} ( i ) = ⌊ \frac{i}{2} ⌋ + ( i mod 2 ) \frac{m}{2} .$$

The permutation maps the left m/2 indices of α to the even indices, and the right m/2 indices of α to the odd indices. Next, permute α according to the permuted indices to get \tilde{α}. For example, assume m=8, and α=[α₀, α₁, α₂, α₃, α₄, α₅, α₆, α₇]. In this case \tilde{α}=[α₀, α₄, α₁, α₅, α₂, α₆, α₃, α₇]. After performing this permutation, the exact same algorithm for DPC described herein may be applied, with \tilde{α} as the LLRs. At the end of the DPC algorithm the best four hard candidates, which may be denoted by \tilde{β}⁽⁰⁾, \tilde{β}⁽¹⁾, \tilde{β}⁽²⁾, \tilde{β}⁽³⁾, have been determined. Lastly, to determine the four final candidates for DSPC, the inverse permutation is applied over the indices of each \tilde{β}⁽ⁱ⁾. In other words, at least one of the DPC tree and the DSPC tree may be decoded by extracting a given number of best candidates from one or more tables (e.g., Table 1 to Table 4) based on a set of input conditions related to values of frozen vectors f included in the at least one of the DPC tree and the DSPC tree.

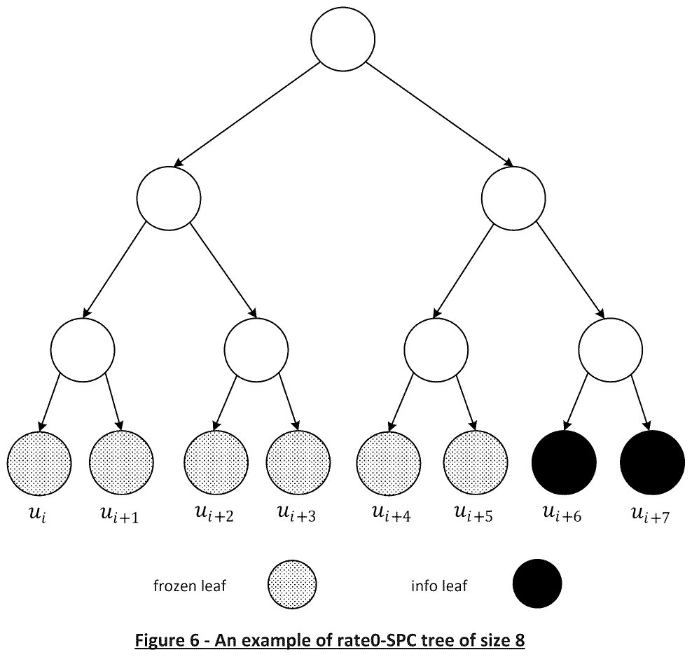

Referring next to FIG. 6, exhaustive search trees of limited size with be discussed using a rate-0 SPC tree of size 8 with arbitrary frozen bit values. As previously noted, various example embodiments include defined special trees of a limited size, including REP-SPC, rate 0-SPC, and REP-rate 1. Various example embodiments employ novel techniques to find a limited number (e.g., four) of best candidates. By using the techniques described herein, the calculation of LLRs in lower levels of the tree may be avoided. It will be noted that the maximal value of LLRs in lower levels of the tree tend to increase in size, and limiting the maximal value of the LLRs, as done by various example embodiments, allows the number of bits required to represent the LLRs to be reduced.

Towards this end, various example embodiments perform an exhaustive search over all possible local codewords—e.g., codewords in a subtree. Each of the possible values in the u values corresponding to the information bits are multiplied by G of the same size of the tree. This method creates 2^{\tilde{k}} possible codewords, where \tilde{k} is the number of info bits in the subtree. A path metric (PM) may be calculated for each of the 2^{\tilde{k}} possible codewords, and then a specific number of (e.g., four) best codewords in terms of PM may be chosen. In an example embodiment, a vector for each of the 2^{\tilde{k}} possible codewords may be generated, and the path metric for each of the 2^{\tilde{k}} possible codewords may be calculated based on the vector for each of the 2^{\tilde{k}} possible codewords.

Refer to the example rate 0-SPC tree of FIG. 6, which has 3 information bits on its right side, and therefore has eight possible codewords candidates.

Let ũ=[uᵢ, uᵢ₊₁, uᵢ₊₂, uᵢ₊₃, uᵢ₊₄, uᵢ₊₅, uᵢ₊₆, uᵢ₊₇]. Assume, for ease of explanation, that the frozen bits in this tree are zeros, i.e., uᵢ=uᵢ₊₁=uᵢ₊₂=uᵢ₊₃=uᵢ₊₄=0. The 8 possible ũ for such a tree are:

$${\tilde{u}}^{0} = [ 0 , 0 , 0 , 0 , 0 , 0 , 0 , 0 ]$$

$${\tilde{u}}^{1} = [ 0 , 0 , 0 , 0 , 0 , 0 , 0 , 1 ]$$

$${\tilde{u}}^{2} = [ 0 , 0 , 0 , 0 , 0 , 0 , 1 , 0 ]$$

$${\tilde{u}}^{3} = [ 0 , 0 , 0 , 0 , 0 , 0 , 1 , 1 ]$$

$${\tilde{u}}^{4} = [ 0 , 0 , 0 , 0 , 0 , 1 , 0 , 0 ]$$

$${\tilde{u}}^{5} = [ 0 , 0 , 0 , 0 , 0 , 1 , 0 , 1 ]$$

$${\tilde{u}}^{6} = [ 0 , 0 , 0 , 0 , 0 , 1 , 1 , 0 ]$$

$${\tilde{u}}^{7} = [ 0 , 0 , 0 , 0 , 0 , 1 , 1 , 1 ]$$

Therefore, the 8 only possible codewords are:

$${β}^{( 0 )} = {\tilde{u}}^{0} {G}_{8 \times 8} = [ 0 , 0 , 0 , 0 , 0 , 0 , 0 , 0 ]$$

$${β}^{( 1 )} = {\tilde{u}}^{1} {G}_{8 \times 8} = [ 1 , 1 , 1 , 1 , 1 , 1 , 1 , 1 ]$$

$${β}^{( 2 )} = {\tilde{u}}^{2} {G}_{8 \times 8} = [ 1 , 0 , 1 , 0 , 1 , 0 , 1 , 0 ]$$

$${β}^{( 3 )} = {\tilde{u}}^{3} {G}_{8 \times 8} = [ 0 , 1 , 0 , 1 , 0 , 1 , 0 , 1 ]$$

$${β}^{( 4 )} = {\tilde{u}}^{4} {G}_{8 \times 8} = [ 1 , 1 , 0 , 0 , 1 , 1 , 0 , 0 ]$$

$${β}^{( 5 )} = {\tilde{u}}^{5} {G}_{8 \times 8} = [ 0 , 0 , 1 , 1 , 0 , 0 , 1 , 1 ]$$

$${β}^{( 6 )} = {\tilde{u}}^{6} {G}_{8 \times 8} = [ 0 , 1 , 1 , 0 , 0 , 1 , 1 , 0 ]$$

$${β}^{( 7 )} = {\tilde{u}}^{3} {G}_{8 \times 8} = [ 1 , 0 , 0 , 1 , 1 , 0 , 0 , 1 ]$$

The PM for each codeword may be calculated as follows:

$$PM = {\sum }_{j ∈ Γ} \vert {α}_{j} \vert , where Γ = \{ i \vert h ( {α}_{i} ) \neq {β}_{i} \} .$$

For that purpose, assume the following LLRs at the root of the tree α=[−1, −2, 1, 3, 4, −3, 1, 1].

$$h ( α ) = [ 1 , 1 , 0 , 0 , 0 , 1 , 0 , 0 ] ⇒$$

$${PM}^{( 0 )} = \vert {α}_{0} \vert + \vert {α}_{1} \vert + \vert {α}_{5} \vert = 6$$

$${PM}^{( 1 )} = \vert {α}_{2} \vert + \vert {α}_{3} \vert + \vert {α}_{4} \vert + \vert {α}_{6} \vert + \vert {α}_{7} \vert = 10$$

$${PM}^{( 2 )} = \vert {α}_{1} \vert + \vert {α}_{2} \vert + \vert {α}_{4} \vert + \vert {α}_{5} \vert + \vert {α}_{6} \vert = 11$$

$${PM}^{( 3 )} = \vert {α}_{0} \vert + \vert {α}_{3} \vert + \vert {α}_{7} \vert = 5$$

$${PM}^{( 4 )} = \vert {α}_{4} \vert = 4$$

$${PM}^{( 5 )} = \vert {α}_{0} \vert + \vert {α}_{1} \vert + \vert {α}_{2} \vert + \vert {α}_{3} \vert + \vert {α}_{5} \vert + \vert {α}_{6} \vert + \vert {α}_{7} \vert = 12$$

$${PM}^{( 6 )} = \vert {α}_{0} \vert + \vert {α}_{2} \vert + \vert {α}_{6} \vert = 3$$

$${PM}^{( 7 )} = \vert {α}_{1} \vert + \vert {α}_{3} \vert + \vert {α}_{4} \vert + \vert {α}_{5} \vert + \vert {α}_{7} \vert = 13$$

Therefore, in this example, the four best codewords in terms of PM are β⁽⁶⁾, β⁽⁴⁾, β⁽³⁾, β⁽⁰⁾.

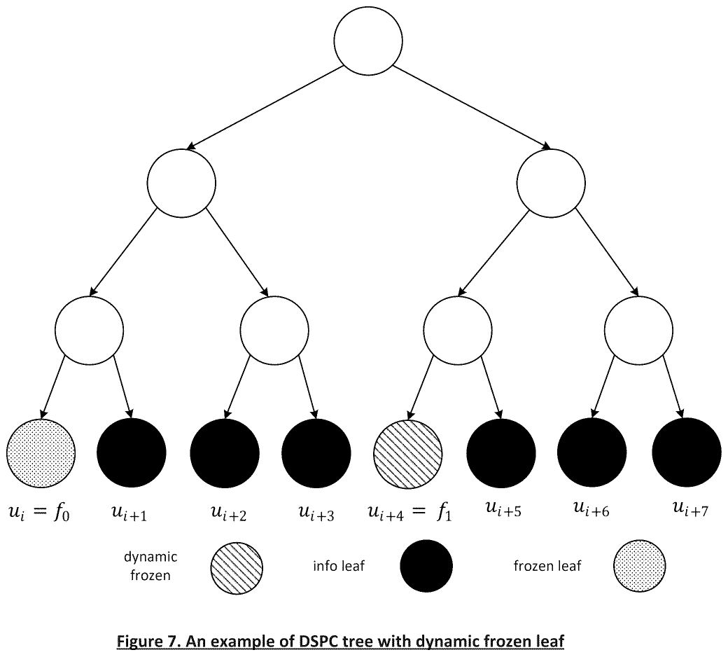

Referring next to FIG. 7, a DSPC tree with a leaf including a frozen bit having a dynamic value will be discussed in accordance with various example embodiments. As previously noted, dynamic frozen bits are frozen bits which are function of previous frozen and/or info bits. Let u be the pre-encoded polar codeword. The bit uᵢ is considered as a delta frozen bit if

$${u}_{i} = {δ}_{i} + {\sum }_{j ∈ {J}_{i}} {u}_{j} , where {J}_{i} ⊆ [ i ] , and {δ}_{i} ∈ \{ 0 , 1.$$

Note that in the SC and SCL decoding, when the decoder reaches the bit uᵢ, the set u_{J}_{ᵢ} of bits are already known, therefore uᵢ can be calculated and treated as a frozen bit. In general, dynamic frozen bits may induce a constraint over the simplified decoder, which complicates the decoding process. Various example embodiments disclosed herein deal with simplified decoding of trees having dynamic frozen bits. In at least some example embodiments, such trees may be treated without additional complexity. However, various example embodiments disclose solutions for cases in which the dynamic frozen bits increase the problem complexity.

Assume a subtree of size m, with u values [uᵢ, uᵢ₊₁, . . . , uᵢ₊ₘ₋₁]. Let uₖ, i≤k≤i+m−1 be a delta frozen bit. If Jₖ contains indices smaller than i, then when the decoder reaches the root of the aforementioned subtree, u_{J}_{ₖ} is known, hence uₖ may be calculated and can be treated as a frozen bit. If Jₖ also contains indices in the range i, i+1, . . . , i+m−1, which are all corresponding to frozen bits, uₖ may also be calculated, because the frozen bits are known.

If Jₖ also contains indices in the range i, i+1, . . . , i+m−1, which correspond to delta frozen bits, the dynamic equations for these bits may be recursively substituted in the equation for uₖ, until uₖ is not expressed as a function of delta frozen bits. If the conditions above still hold, uₖ can be calculated. However, if uₖ is a function of information bits within its tree, the constraints over possible codewords β for this tree changes.

Because this scenario complicates the suggested simplified decoding algorithms disclosed herein, various example embodiments employ one or two possible solutions: 1) split the special tree into smaller trees until the dynamic frozen bit is independent of info bits contained within the tree itself (for example, one or more info bits on which the value of the dynamic frozen bit depends are not included in the same tree as the dynamic frozen bit); or 2) during the code planning phase, where feasible, modify the dependencies of dynamic frozen bits with other bits, such that the dynamic frozen bits will be independent of info bits contained within the tree itself.

Continue to refer to FIG. 7, which illustrates a DSCP tree with dynamic frozen bit. Assume uᵢ₋₁₈+uᵢ₋₃+uᵢ=uᵢ₊₄. In this case, at the root of this tree, the bits uᵢ₋₁₈, and uᵢ₋₃ have already been decoded, because their indices are smaller than the smallest index in this tree which is i. The bit uᵢ is a frozen bit, therefore the value of the bit uᵢ is known when this tree root is reached. Because uᵢ₋₁₈, uᵢ₋₃, and uᵢ are known, uᵢ₊₄ can be calculated before decoding of the tree in FIG. 7 is started. Because it is known to treat uᵢ as a frozen bit, the decoder for DSPC described previously may be applied.

On the other hand, if for example uᵢ+uᵢ₊₁+uᵢ₊₃=uᵢ₊₄, this tree cannot be decoded in a simplified way as uᵢ₊₄, depends on uᵢ₊₁, and uᵢ₊₃, which are information bits that introduce constraints on the simplified decoding tree.

In at least one example embodiment, the tree may be split into two separate trees. In this example, yielding two SPC trees. The left SPC tree contains no dynamic frozen bits and can be decoded using the algorithm already discussed. The right SPC tree, however, contains a dynamic frozen bit. Note, however, that the dynamic frozen bit of the right SPC tree has become a function of bits which are not currently part of this subtree. Therefore, this dynamic frozen bit is known by the time the root of this subtree is reached for decoding, which allows the dynamic frozen bit to be treated as a non-dynamic frozen bit.

In other example embodiments, at the planning stage, the tree may be constructed so that that uᵢ₊₄, is not a function of uᵢ₊₁, and uᵢ₊₃. This planning-stage solution may be possible if dynamic equations are not strictly forced.

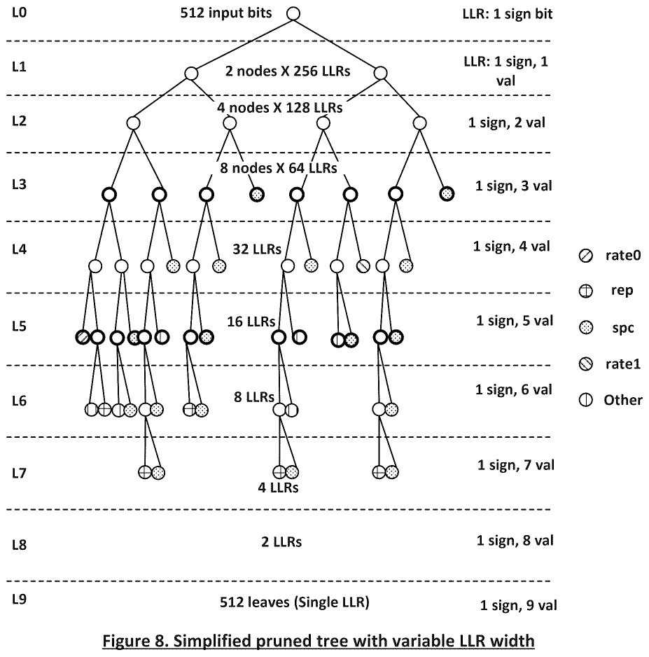

Referring next to FIG. 8, a simplified pruned tree with variable likelihood log ratio widths will be discussed in accordance with various example embodiments. In various example embodiments a pruned tree is “simplified” by defining sub sub-trees that may be decoded in a higher layer, while yielding the same results as decoding the leaves in the lowest layer of the tree. This method may enable significantly pruning the tree to significantly reduce tree complexity—essentially collapsing certain subtrees to be represented by the subtrees' root nodes. Various example embodiments prune trees based on additional subtrees for common node patterns, and also define special subtrees for substantially all 4-LLR subtrees, to avoid have to go down to the leaves. Furthermore, defining special subtrees for 4-LLR subtrees up to layer 7 enables a reduction in the bit resolution of LLR calculations that hardware should support. Various types of special trees, and processes for handling each, have been described above.

Based on the polar tree and the soft calculations, it may be observed that in the first, or upper, layers of a tree, the LLR may be represented using reduced number of bits, and that the number of bits used to represent the LLR increases with each subsequent layers. This is represented by the simplified pruned tree illustrated in FIG. 8.

The first layer (L0) is the channel input, which has a value of “0” or “1”. Only the sign bit is maintained for this layer. So only a single bit in a register is needed to represent the Log-Likelihood Ratio (LLR). In at least one example embodiment, a zero in the sign bit indicates a negative number, and a 1 in the sign bit represents a positive value. Consequently, a zero may be represented as a negative, and a one may be represented as a positive. Note that for purposes of calculations involving the LLR of L0, an LLR value of “0.5” may be assumed, so that a zero value in the LLR of L0 has an LLR of −0.5, and a one value in the LLR of L0 has an LLR of +0.5, even though only the sign bit is maintained. In another example, a zero in the sign bit indicates a positive number, and a 1 in the sign bit represents a negative value.

In the next layer L1, LLR values result from L0 combinations and are one of: {0, 1, −1}, and may be represented using 1 sign bit and 1 value bit. In layer L2, LLR values may be represented with 1 sign bit and 2 value bits, and so on down through layer L9, which uses one sign bit and 9 value bits to represent the LLR values.

Note that there are no L9 nodes illustrated in the simplified pruned tree of FIG. 8, because the tree has been pruned using special subtrees, including the 4-LLR subtrees defined up to layer L7. Note that, in layer L7, LLRs may be represented by a single 8 bit register (1 sign bit and 7 value bits). Using this technique and/or other techniques described herein, some example embodiments may contribute to reducing the gate count of the decoder hardware by limiting the register size used to represent LLRs, because the LLRs of the lowest levels of the tree need not be directly determined.

In various example embodiments, soft calculations may, but need not, be performed by separate hardware, according to the layer in the tree. For example, because the first 3 layers (L0−L2) are based on single input bits they may all be calculated in a single cycle. Any complexity in these layers will result from the need to read historical hard decision (HD) bits per list.

In some example embodiments, LLR calculation from Layer L3-L7, recursively traverses the tree, until a “special subtree” is reached. This makes the end point of the calculation the root node of the special sub sub-tree, which may be in layer L3, L4, L5, L6 or L7. In at least one example embodiment, the decoder calculates four layers sequentially, and the decoder outputs the selected layer currently being calculated as discussed with reference to the remaining figures.

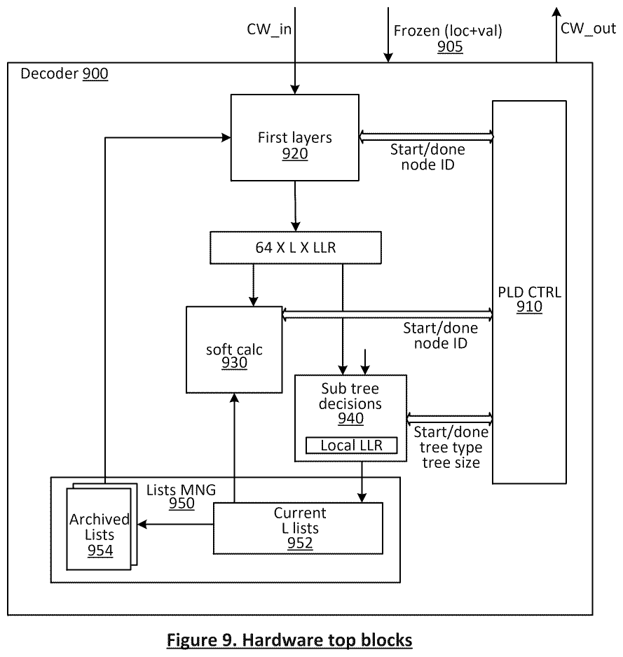

Referring next to FIG. 9, a decoder 900 will be discussed in accordance with various example embodiments. The decoder 900 includes hardware top blocks including a programmable logic device (PLD) control (CTRL) block/module 910, that controls the decoding tasks at least in part by activating other hardware blocks/modules (for example, coordinates operations of a plurality of decoder modules to perform simplified sequential list decoding of a polar encoded codeword); a first layers block/module 920, which calculates LLRs of the upper layers of the tree (e.g., a pruned decoding list tree to be described below); a soft calculation block/module 930, which calculates LLRs of the mid-layers (e.g., L3-L7) of the tree; a subtree decisions block/module 940, which calculates hypotheses (e.g. most likely values at a node, which represent decisions for potential decode continuation) for a current sub tree and outputs a given number of lists of these hypotheses; and a list manager (MNG) 950, which manages current lists 952 and archived lists 954 generated by the subtree decisions block/module 940. In some example embodiments, a variable number of codewords may be decoded in parallel with a variable number of lists. In FIG. 9, CW_in may represent an input polar encoded codeword, and CW_out may represent a decoded codeword.

In some example embodiments, the PLD control block/module 910 maintains decode state variables (for example, using node indexes to be described below), receives the frozen-qualifiers vector 905, analyzes the tree structure, handles node indexing, performs tree pruning, and activates or otherwise controls the first layers block/module 920, the soft calculation block/module 930, the subtree decisions block/module 940, and/or other hardware, firmware, or software blocks as needed during the decoding process. In some example embodiments, the frozen-qualifiers vector 905 (or, information included in the frozen-qualifiers vector 905) may define values and locations of the frozen bits having arbitrary values within the polar encoded codeword. In some example embodiments, the frozen-qualifiers vector 905 may define at least one of the frozen bits as a dynamic frozen bit.

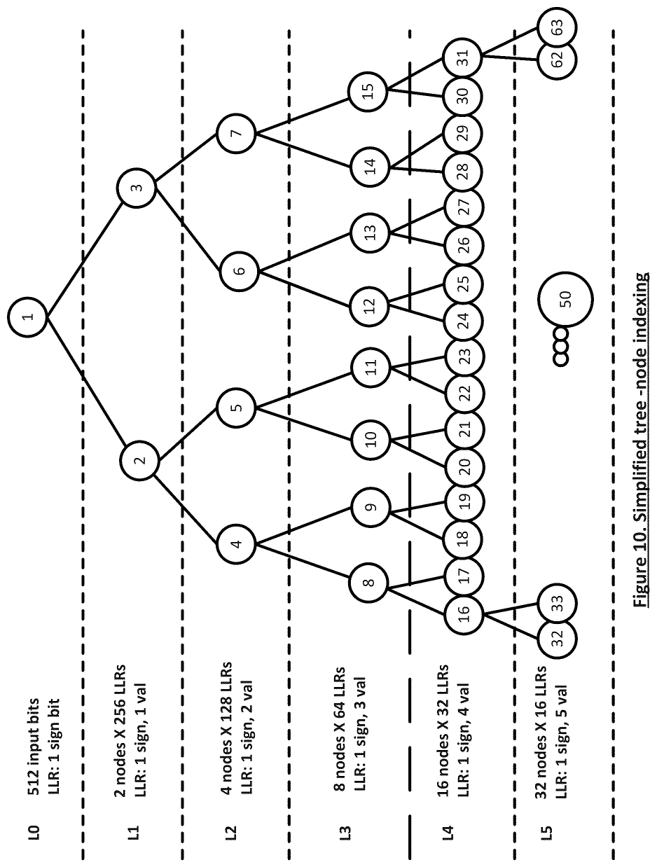

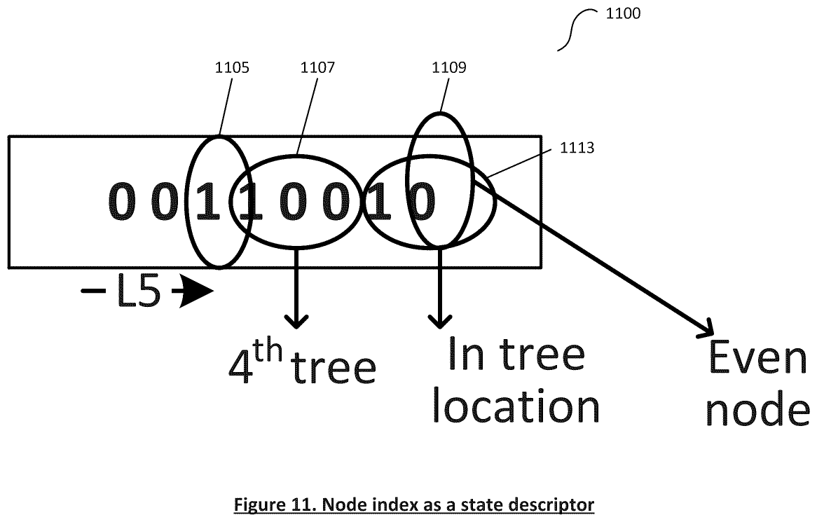

In some example embodiments, analyzing the tree structure and identify special subtrees to be used for pruning relies, at least in part, on the node indexing, and information included in the frozen-qualifiers vector 905. For example, the pruned decoding list tree may be generated by collapsing special subtrees identified based on the frozen-qualifiers vector 905. Referring next to FIGS. 10 and 11, node indexing will be discussed in accordance with various example embodiments.

TABLE 5

| | | Input/ | | |
|---|---|---|---|---|
| Interface | | output | | |
| (i/f) | signal name | (I/O) | width | description |
| | clk | I | | |
| | rst | I | | |
| ctrl | frozen loc | I | 512 | Frozen bits locations. 1 |
| | | | | if the bit is a frozen bit, |
| | | | | 0 if info bit. |
| first layers | first_layers_start | O | 1 | activates the first layer |
| | | | | logic. |
| | first_layers_node_id | O | 3 | 3 LSB bits of the |
| | | | | required node ID |
| | | | | (“000” for n8, . . . , |
| | | | | “111” for n15). valid |
| | | | | with first layers start. |
| | first_layers_done | I | 1 | indication from first |
| | | | | layer logic. |
| soft calc | soft calc_start | O | 1 | activates the soft calc |
| (mid) | | | | logic. |
| | soft_calc_node_id | O | 4 | (TBD, assuming 4 |
| | | | | layers in a cycle) |
| | soft_calc_done | I | 1 | indication from soft |
| | | | | calc. |
| Sub-Tree | sub_tree_start | O | 1 | |
| decisions | sub_tree_type | O | 3 | type of the simplified |
| | | | | tree. //TBD-define the |
| | | | | codes |
| | sub_tree_degree | O | 5 | 4/8/16/32/64 (also to |
| | | | | lists management) |
| | sub_tree_done | I | | indication from subtree |
| | | | | decisions |
| Lists | current_node_pointer | O | 4 | points to the update |
| manager | | | | location in a 64 b sub- |
| | | | | vector.write is in 4 b |
| | | | | resolution. |

FIG. 10 illustrates a pruned tree with nodes having index values of 1 to 63. In some example embodiments, an original tree constructed from a received codeword may have index values ranging from 1 to 1023. In various example embodiments, a pruned tree constructed by collapsing special trees into a single node of the pruned tree may have indexes ranging from 1 to 255, excluding the pruned nodes of subtrees.

FIG. 11 illustrates a node index (or referred to as an index of a node) 1100, which various example embodiments of the PLD control block/module 910 use as a state indicator. The first “1” in the node index as counted from the most significant bit (MSB) of the register, indicates the layer in which the node is located. Three bits of the node index indicate the 64b subtree in which the node is located, and two bits indicate the location of the node within the 64b subtree. An even index, e.g., where the least significant bit is zero, indicates that the node will require a left calculation, and an odd index, e.g., where the least significant bit is one, will require a right calculation. In at least some example embodiments, the index may know the path of calculations (left\right) from the root node of the subtree.

Consider the following example embodiment, including a node having a node index 1100 with an index value of 50, as illustrated in FIG. 11. The index value of 50 (decimal) is shown in its binary representation, 00110010. The even index, whose least significant bit 1109 is zero, illustrated in FIG. 11 may indicate that the node will require a left calculation. The left-most “1” (i.e., 1105) is in the 5^{th} bit (counting from zero beginning at the least significant bit, so the node is in layer L5. If the left-most “1” had been in the 6^{th} bit, the node would have been in layer L6.

The next 3 bits (i.e., 1107) of node index 1100 after the left-most “1” indicate the subtree of layer L5 to which the node belongs. In the illustrated example embodiment, those 3 bits have the binary value 100 (decimal 4), and indicate that the node belongs to the fourth subtree of layer L5. The following 2 bits (i.e., 1113) (3 bits for layer L6, and 4 bits for Layer L7), indicate the location of this node in layer L5 of the 64b sub tree. Note that there are 4 nodes of layer L5 in the subtree.

In one or more example embodiments, the PLD control block/module 910 controls the decoding process to begin at the first node of layer L3, which is node 8. The PLD control block/module 910 scans for subtrees and activates the soft calculation block/module 930 to calculate LLR of the sub-trees identified by the scan. The soft calculation block/module 930 returns the calculated LLRs to the PLD control block/module 910, proceeds to the next in the 64b structure based on the indexes of the nodes. Once the subtrees of the first node of layer L3 have been processed, the PLD control block/module 910 processes the next node of layer L3 until all nodes of layer L3 have been processed.

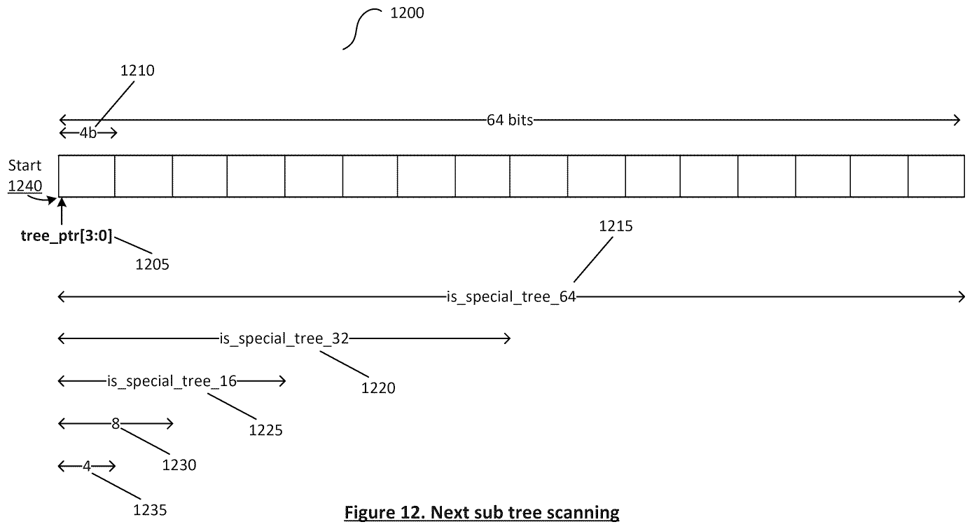

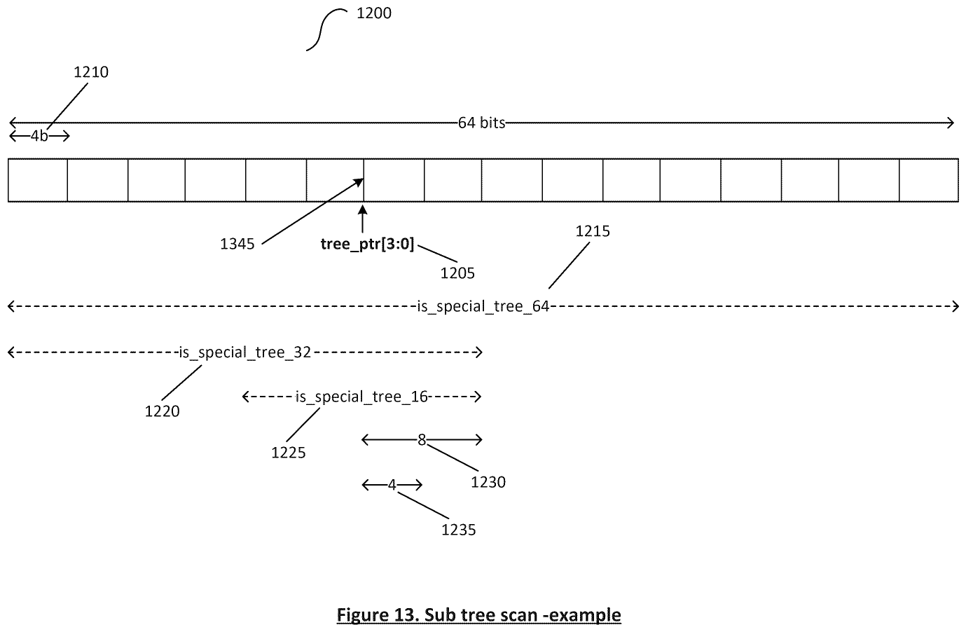

Referring next to FIGS. 12-13, next-subtree scanning will be discussed in accordance with various example embodiments. In some example embodiments, analysis of a tree by the PLD control block/module 910 includes identifying (e.g., scanning for) subtrees using a tree-analysis structure 1200, as illustrated in FIG. 12. In various example embodiments, the tree-analysis structure 1200 is 64 bits long, and the PLD control block/module 910 advances a tree pointer (tree_ptr[3:0]) 1205 in 4 bit increments while scanning for subtrees. The PLD control block/module 910 may attempt to identify a 64-degree special subtree 1215, a 32-degree special subtree 1220, a 16-degree special subtree 1225, an 8-degree special subtree 1230, and/or a 4-degree special subtree 1235. It is always true that a 4-degree special subtree 1235 is detected.

In at least one example embodiment, the PLD control block/module 910 retrieves frozen bit values and locations from the frozen-qualifiers vector 905, and uses the information from the frozen-qualifiers vector 905 and analyzes the tree beginning at the first node in layer L3 (e.g., node 8) to identify any 64-degree special subtrees of the original tree structure.

If a 64-degree special subtree 1215 is detected at the first node in layer L3, the PLD control block/module 910 instructs the soft calculation block/module 930 to soft-decode the 64-degree special subtree 1215, and advances the tree pointer 1205 according to the decoded size. In at least one example embodiment, if a 64-degree special subtree 1215 is detected and decoded, the tree pointer 1205 advances to the end of the tree-analysis structure 1200, and the PLD control block/module 910 uses the information from the frozen-qualifiers vector 905 to iteratively analyze tree structures of the remaining nodes in layer L3 using the tree-analysis structure 1200, or another tree-analysis structure like the tree-analysis structure 1200.

If no 64-degree special subtrees are detected at the first node in layer L3, the PLD control block/module 910 iteratively attempts to identify smaller special subtrees of the first node in layer L3. Upon detection of any smaller special subtrees, the PLD control block/module 910 activates the soft calculation block/module 930 to soft-decode the identified special subtree, and advances the tree pointer 1205 according to the decoded size.

As noted above, at least a 4-degree special subtree 1235 is always identified and soft decoded by the soft calculation block/module 930, so the tree pointer 1205 is advanced by at least 4 bits to its next position.

In various example embodiments, larger special subtrees are prioritized over smaller special subtrees, but there may be situations in which not all subtree sizes are possible. In the example embodiment of FIG. 13, for instance, the tree pointer 1205 has advanced to a second position 1345 of the tree-analysis structure 1200, at which 24 bits of 64 bits have been decoded. At the current position of the tree pointer 1205, 64-degree special subtrees, 32-degree special subtrees, and 16-degree special subtrees are not possible, so the PLD control block/module 910 attempts detection of only 8-degree special subtrees, and/or 4-degree special subtrees.

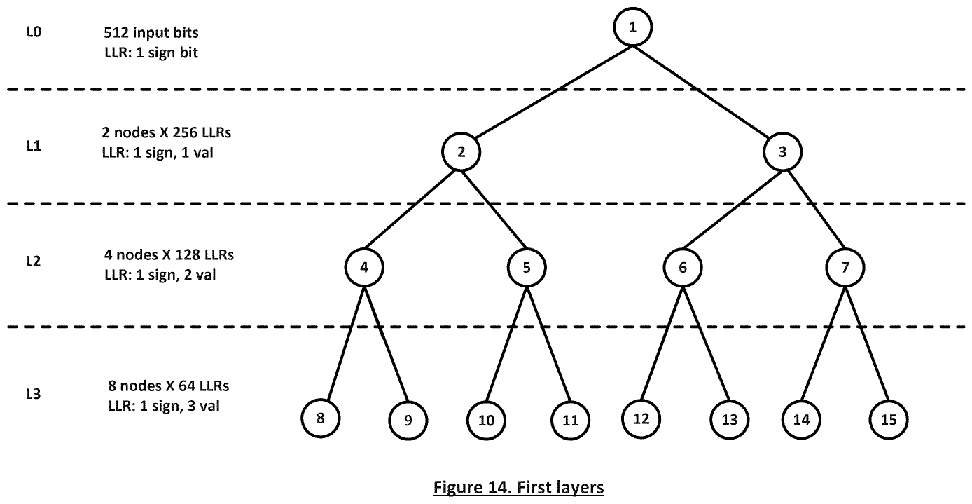

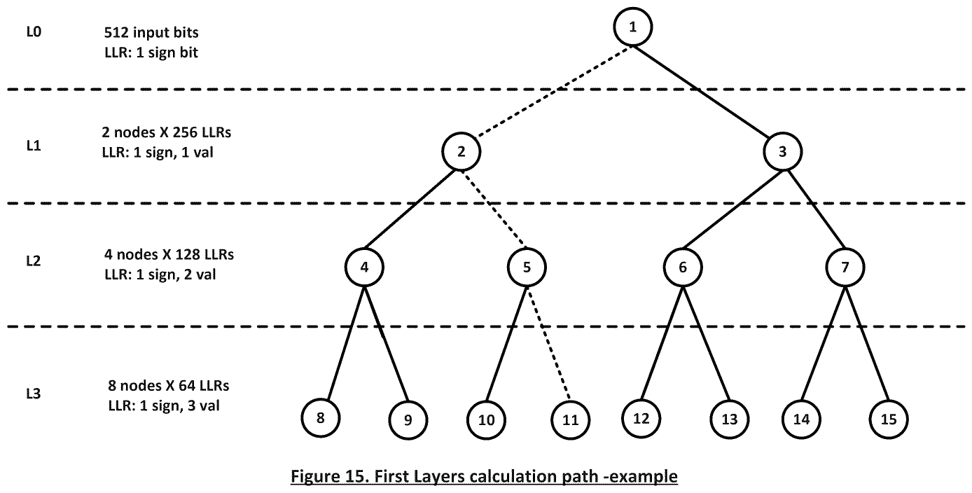

Referring next to FIGS. 14-15, soft-calculation of first (upper) layers of a tree (e.g., pruned decoding list tree) will be discussed in accordance with various example embodiments. In one or more example embodiments, soft-calculation of the upper layers is performed by first layers block/module 920 (FIG. 9) (for example, to generate first outputs including soft values (LLRs) for nodes in the upper layers of the pruned decoding list tree) in response to an activation signal from the PLD control block/module 910. In various example embodiments, the PLD control block/module 910 also pass the location (or node identifier (ID)) of a node for which soft calculations are to be performed to the first layers block/module 920. In some example embodiments, the soft calculations may be concurrently performed for each of a plurality of (e.g., three) upper layers.

For example, the first layers block/module 920 may perform first soft calculations for nodes identified by node identifiers, a polar encoded codeword, and up to L lists including past decisions from the list manager module 950. In one or more example embodiments, the first layers block/module 920 calculates 64 soft values (LLR) based on the input and past decisions (“u”). In some such example embodiments, the first layers block/module 920 calculates three consecutive soft calculations of fixed degree. Each of the three soft calculations may be either a “left” or “right” calculation. “Left” calculations may be based on two upper soft values (x,y), where f(x,y)=sign(x)sign(y)·min (|x|,|y|).

“Right” calculations may be based on 2 upper soft values (x,y) and a hard decision of the right node, c: g(x, y, c)=c? (y−x): (y+x). For calculations involving the first layer L0, recall that only bit (the sign bit) is used for first layer L0. In at least some example embodiments, the value of each bit is assumed to be “0.5”.

Because the first 3 layers are based on single input bits, Layers L0-L2 may be calculated in one cycle. Any complexity in these layers will result from the need to read historical hard decision bits per list. It can be observed that “left” calculations keep the range of the soft values, while right calculations double it. Therefore, an additional bit for each subsequent layer is needed to represent the value in some example embodiments.

In some example embodiments there are exceptions to the above. In particular, the first right calculation per layer, (node3, node5, node9), requires special attention: Because the values in the input layer (L0) have no representation in bits, the right calc should assume value of “0.5”, and therefore possible results would be {−1, 0, 1}.

When “right” calculation result is 0, the sign will be assigned arbitrarily according to the hard decision bit.

An example of an upper layer soft calculation is shown in FIG. 15. Logic in the first layers block/module 920 receives a node ID 11 (decimal) from the PLD control block/module 910. The three least significant bits (LSBs) of the node ID (e.g., node index) are “011”. The LSBs of the node ID direct the first layers block/module 920 to perform the following calculations: a left calculation from L0 to L1 based on bits of node 1; a “Right” calculation, from L1 to L2 based on “0.5” (first right calculation), sign bits of node 2, and hard decisions of node 4; and a “Right” calculation, from L2 to L3 based on LLRs of node 5 and hard decisions of node10.

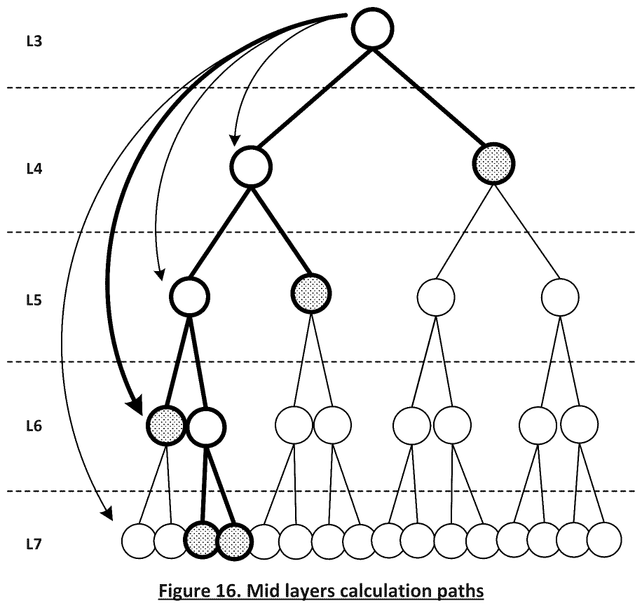

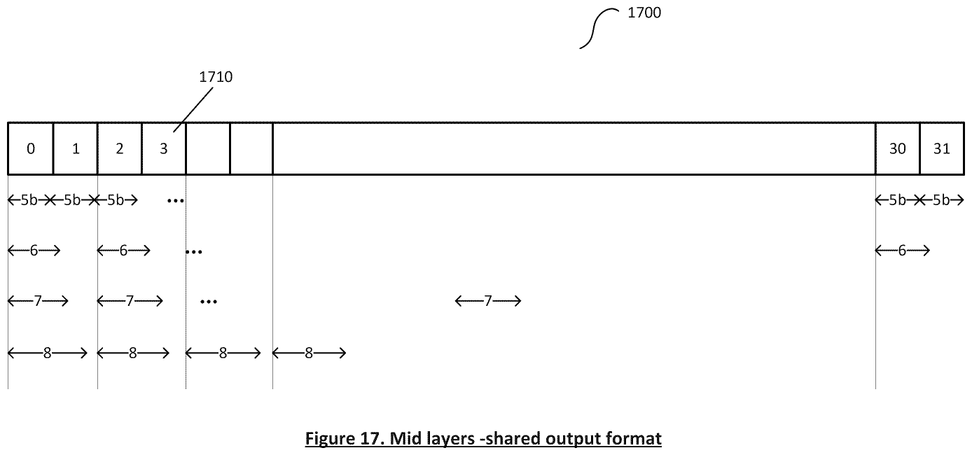

Referring next to FIG. 16, mid-layers calculations will be discussed in accordance with various example embodiments. In various example embodiments, the soft calculation block/module 930 (FIG. 9) performs soft calculations (e.g., mid-layer soft calculations) for the mid layers L3-L7 of a tree (e.g., a pruned decoding list tree). Left\Right calculations are defined according to the path, as discussed previously with respect to FIGS. 14-15. As also discussed previously, first right calculations may replace LLR values with “0.5”, so that the sums are {−1, 0, 1}. In some such example embodiments, when the result of a right calculation is zero, the sign of zero may be set according to “y” (the received signal at the decoder). In various example embodiments, two or more consecutive calculations will be done in one cycle, (according to timing conditions). The endpoint layer for the mid-layer soft calculations may be defined by a control signal from the PLD control block/module 910. The output will be selected accordingly, as discussed with respect to FIG. 17. In some example embodiments, the mid-layer soft calculations may generate second outputs, the second outputs may include L lists of path metrics for each root node of a subtree of the pruned decoding list tree, each path metric may be associated with a path from the root node of the subtree to a terminal node of the subtree, and each of the L lists may include K best path options, and thus the L lists may cumulatively include L×K best path options. In some example embodiments, the mid-layer soft calculations may be concurrently performed for a plurality of subtrees of the pruned decoding list tree.

Referring next to FIG. 17, a mid-layers shared output format will be discussed in accordance with various example embodiments. The output of the soft calculation block/module 930 (FIG. 9) may be sampled according to the layer of the desired target node. According to some example embodiments, in case of nodes of layer L4, 32 LLR values 1710 of 5 bits (1 sign bit and 4 value bits) are output to a list 1700, for a total of 160 bits per list. In case of deeper layers (L5-L7), which have fewer LLR values each including a larger number of value bits, the LLR may be written on 2 LLR allocations of layer L4, while maintaining the same maximum number of available bits in the output list. As illustrated by list 1700, for example, LLR values of layer L5 consume 6 bits (1 sign bit and 5 value bits); LLR values of layer L6 consume 7 bits (1 sign bit and 6 value bits); LLR values of layer L7 consume 8 bits (1 sign bit and 7 value bits). Note that the output of the layer L7 will produce 20 LLR values of 8 bits each.

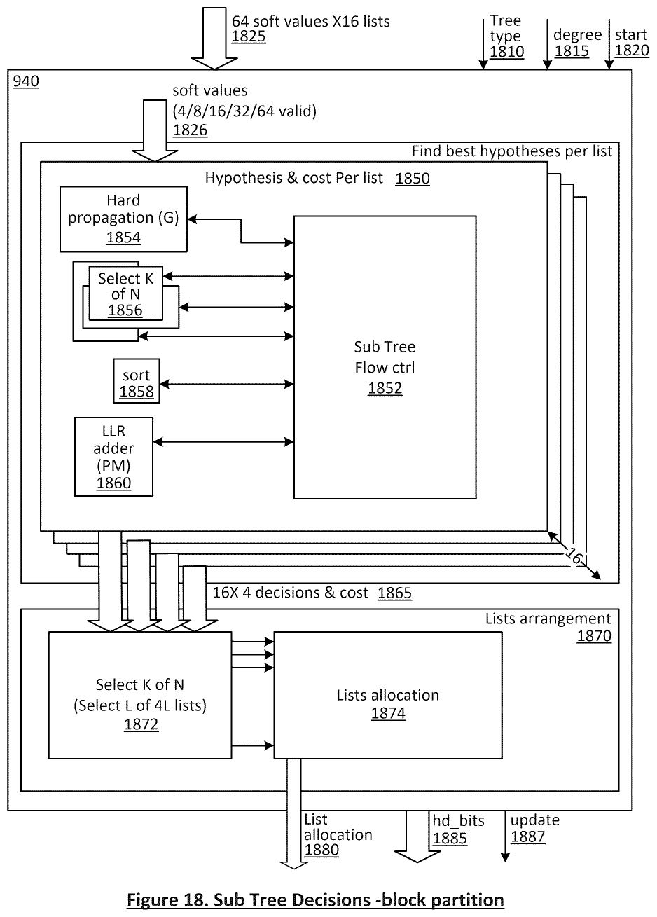

Referring next to FIG. 18, a subtree decisions block/module 940 will be further discussed in accordance with various example embodiments. Subtree decisions block/module 940 receives soft values and lists 1825, tree type 1810, degree 1815, and a start control signal 1820, while outputting list allocation 1880, hard decision bits (hd_bits) 1885 and an update signal (e.g., a hard decision bit update signal) 1887.

Subtree decisions block/module 940 includes a hypothesis/cost per list module 1850, which further includes a sub tree flow control module 1852, a hard propagation module 1854, a selection module 1856, a sort module 1858, and an LLR adder module 1860. The hypothesis/cost per list module 1850 receives soft values 1826 and outputs decisions and costs 1865 for multiple lists. In the illustrated example embodiment, there are 16 instances of the hypothesis/cost per list module 1850, so that 16×4 decisions and costs 1865 for 16 lists may be concurrently generated. Note that the number of instances of the hypothesis/cost per list module 1850 may be generalized to L instances, so that there may be greater or fewer instances in some example embodiments.

The sub tree flow control module 1852 activates and manages the operation of the other modules included in the hypothesis/cost per list module 1850. The hard propagation module 1854 may calculate hard decisions and/or hypotheses (G), selection module 1856 may make decisions regarding which hypotheses are the best (in terms of LLR and cost), sort module 1858 may sort lists in accordance with the decisions made by selection module 1856, and the LLR adder module 1860 may combine LLRs associated with individual nodes to generate an additional cost (the path metric).

Subtree decisions block/module 940 also includes a list arrangement module 1870, which includes a list selection module 1872 and a list allocation module 1874. The list selection module 1872 receives the decisions and costs 1865 output by the hypothesis/cost per list module 1850, while the list allocation module 1874 generates the list allocation 1880, which is output by the list arrangement module 1870.

In one or more embodiments, the subtree decisions block/module 940 is built to perform two primary tasks: 1) find best hypotheses per list (L duplications of at least some hardware components); and 2) select and reallocate L lists.

In various example embodiments, the flow to find the best hypotheses is according to the tree type and size. The different trees share some common calculations, and may implemented by the same hardware. Calculations may be performed, or skipped, according to the tree type. In an example embodiment, the hypotheses and costs for each of K best path options included in each of the L lists may be calculated according to a size and a type of the pruned decoding list tree

For example, the best path may be determined out of the L×K best path options based on the hypotheses and costs of each of the K best path options included in each of the L lists, and a hard decision function. In an example of operation according to at least one example embodiment, a vector of LLR values, e.g., soft values and lists 1825, is received for each list by the subtree decisions block/module 940, which calculates the best 4 hard decisions and their cost per list using hard propagation module 1854. The selection module 1856 selects the best 16 path options from the hypotheses (up to 16×4 in at least one example embodiment). In an example embodiment, the subtree decisions block/module 940 may select a best list of the L lists, and the best list may include a best path of the L×K best path options. In an example embodiment, a decoded codeword may be output based on the best path.

The following table summarizes the tasks performed by the subtree decisions block/module 940.

TABLE 6

| | | | | Parallel | |
|---|---|---|---|---|---|
| | | | | hard- | |
| | Required | | | ware | |
| | in | | | (HW) | |
| Task | types | Degree | Description | per list | Latency |
| Find | SPC | 8 or | Find minimal 4 LLR | 1 | 2 |
| minimal | Rate1 | higher | values of 2s. | | |
| LLR-K | | | HW should support | | |
| from N | | | the following | | |
| | | | configurations to | | |
| | | | allow minimal | | |
| | | | latency, (K, N, W) = | | |
| | | | (4, 8, 6), (4, 16, 5), | | |
| | | | (4, 32, 4), (4, 64, 3) | | |
| | DPC | 16 or | The LLR is split to 2 | 2 | 1 |
| | DSPC | higher | groups, and | | |
| | | | therefore 2 | | |
| | | | selections are | | |
| | | | required, with each | | |
| | | | group including half | | |
| | | | of the values. | | |
| | | | (K, N, W) = | | |
| | | | (4, 8, 5), (4, 16, 4), | | |
| | | | (4, 32, 3) | | |
| Find | SPC | all | Sort the 4 minimal | 2 | 1 |
| minimal | Rate1 | | LLR to find their | | |
| LLR-sort 4 | DPC | | internal order | | |
| | DSPC | | | | |
| build | rate0 | all | calculate 1 to 16 | 16 | 1 |
| hypotheses | REP | | (according to type) β | | |
| | EREP | | vectors from (hard | | |
| | REP-SPC | | propagation on G) | | |
| build | All | all | Calculate the cost of | 16 | 1 |
| hypotheses | | | 1 to 16 hypotheses | | |
| and | | | according to type. | | |
| calculate | | | (In rate0, REP, EREP | | |
| | | | and REP-SPC8) | | |
| additional | | | hypotheses are built | | |
| cost (PM | | | from the leaves, in | | |
| addition) | | | the other types it is | | |
| | | | built from the LLRs. | | |
| | | | In the first sub tree, | | |
| | | | where the LLR | | |
| | | | values are not | | |
| | | | explicit (+/−0.5), | | |
| | | | sum the LLRs of | | |
| | | | opposite direction | | |
| | | | and divide by 2 | | |
| | | | (shift right) | | |
| | | | in Ratel and SPC, | | |
| | | | also select the 4th | | |
| | | | hypothesis out of 5. | | |
| select best | DPC | all | Select 4 hypotheses | 1 | 2 |
| hypotheses | DSPC | | of minimal cost. | | |
| | REP-SPC8 | | (Select from 4 of up | | |
| | | | to 16) | | |
| | | | (ratel and SPC | | |
| | | | selections were | | |
| | | | made on-the fly in | | |
| | | | previous stage) | | |
| Calculate | all | all | can be done during | — | — |
| total PM | | | previous stages | | |
| Select 16 of | all | all | (Latency may be | | 6 |
| 64 HW | except rate0 | | reduced if the PM | | |
| | and first | | bits (8 bits will take | | |
| | lists | | 4 cycles) or make | | |
| | | | the “median” | | |
| | | | decision earlier, | | |
| | | | losing some | | |
| | | | precision) | | |
| lists | all | all | based on “select 16 | 1 | 1 |
| selection | except rate0 | | of 64” HW results, | | |
| | and first | | select the final 16 | | |
| | lists | | lists. | | |
| Allocate | all except | | calculate and output | 1 | 1 |
| lists | rate0 and | | bit allocations. | | |
| | first lists | | | | |

In at least one example embodiment, signals received and transmitted from an interface of the subtree decisions block/module 940 may be as shown in the following table.

TABLE 7

| i/f | signal name | I/O | width | description |
|---|---|---|---|---|
| | clk | I | | |
| | rst | I | | |
| PLD CTRL | sub_tree_degree | I | 5 | The number of bits to be |
| | | | | written. 4/8/16/32/64. |
| | curr_node_ptr | I | 4 | Points to the location in the |
| | | | | 64 b register. writes in X4 b |
| | | | | resolution. |
| Sub-Tree | hd_bits | I | 16 × 64 | up to 64 bits per list, |
| | | | | according to tree size (update |
| | | | | resolution). |
| Decisions | | | | The data is aligned to the |
| | | | | write location. |
| | hd_bits_update | I | 1 | hd_bits qualifier |
| | list_allocation | I | 16 × 4 | The assigned list to the |
| | | | | allocation. There are 16 |
| | | | | allocations, but when list “l” |
| | | | | splits, it will be written to |
| | | | | allocation “l” and to another |
| | | | | allocation that is free. |
| L0-L3 Soft | lists_data | O | 7 × 16 × 64 | current and archive lists, for |
| calc | | | | L0-L3 soft calculations. |

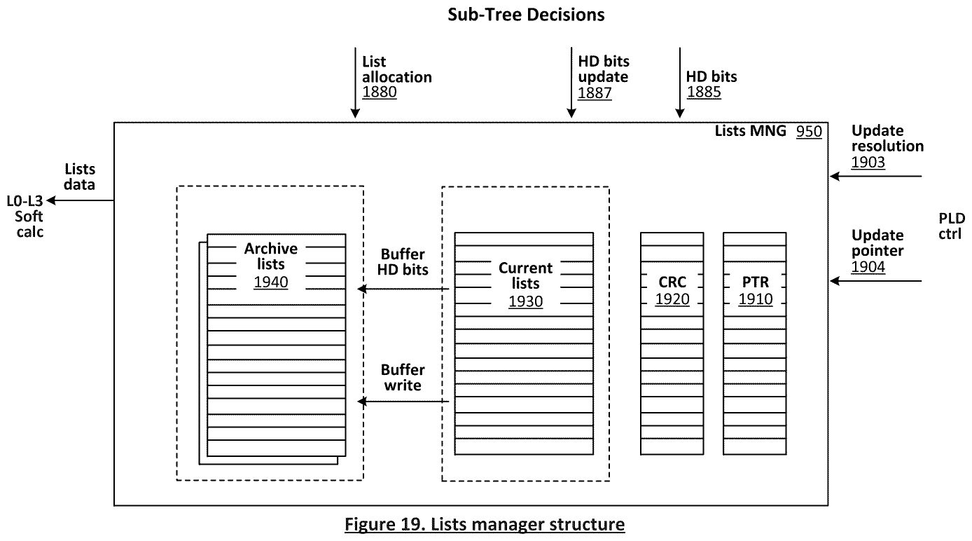

Referring next to FIG. 19, a list manager 950 will be discussed in accordance with various example embodiments. In various example embodiments, the list manager 950 receives an update resolution signal 1903 and a pointer signal 1904 from the PLD control block/module 910. The list manager 950 also receives the list allocation 1880, the hard decision bits 1885, and the update signal 1887 from the subtree decisions block/module 940. The list manager 950 manages an archive pointer buffer (PTR or Arch ptr) 1910, a cyclic redundancy check (CRC) buffer 1920, a current lists buffer 1930 and archive list buffers 1940 based on the information and signals received from the subtree decisions block/module 940 and the PLD control block/module 910.

In some example embodiments, the current 64 bits of each list indicated by the list allocation 1880 are maintained in current lists buffer 1930, which may include L registers of 64 bits with a write-resolution of 4 bits. In some such example embodiments, once calculation of a 64b tree is complete, the values in the current lists buffer 1930 may be written to the “archive list buffers 1940, freeing the current lists buffer 1930 for use with the next 64b tree.

Some example embodiments employ seven archive list buffers of 16×64 bits, with write resolution of 64 bits. Each list may be assigned a 4b pointer stored in the archive pointer buffer 1910, which points to the beginning of the list in the archive list buffers 1940.
In addition to the list buffers, the CRC buffer 1920 maintains a cumulative CRC per list. Although the CRC buffer 1920 may not be directly related to the individual lists, it may be maintained “on the fly” based on the current lists data.

According to some example embodiments initialization of the list manager 950 may include initializing an archive pointer in the archive pointer buffer 1910 with its own index, for each 64 bit list. The CRC buffer 1920 may be initialized to the dynamic-delta-frozen when decoding starts.

Once the subtree decisions block/module 940 is done calculating the hard decisions, it outputs new bits (X16 lists) via the update signal 1887, and new list allocations. The current lists may be copied over one or more free lists stored in the current lists buffer 1930, and concatenate any new lists in accordance with the new list allocations. Database, CRC, and archive pointers related to the new lists may also be copied.

Once done updating the last segment of a 64b tree, the “current lists” in the current lists buffer 1930 may be copied to the next archive list buffer in the archive list buffers 1940. Copying the existing archive lists may be performed according an archive pointer stored in the archive pointer buffer 1910.

In some example embodiments CRC and dynamic frozen bits may be handled as follows. At the start of decoding of every 64 leaves sub tree, the list manager 950 receives an indication of the start of the decoding and the equation for each bit of the CRC and dynamic frozen bits. After that, for every decoded sub tree, the list manager 950 updates the CRC and dynamic frozen bits per list, according to the given equations. The list manager 950 also receives the list allocation signal, which represents which list is a copy of a different list. To the list manager 950, this means that before the update of the CRC and dynamic frozen bits per list by the equations, the values should be updated in each such list. Near the start of the decoding of every subtree, the CRC and dynamic frozen bits for each list are validated and updated.

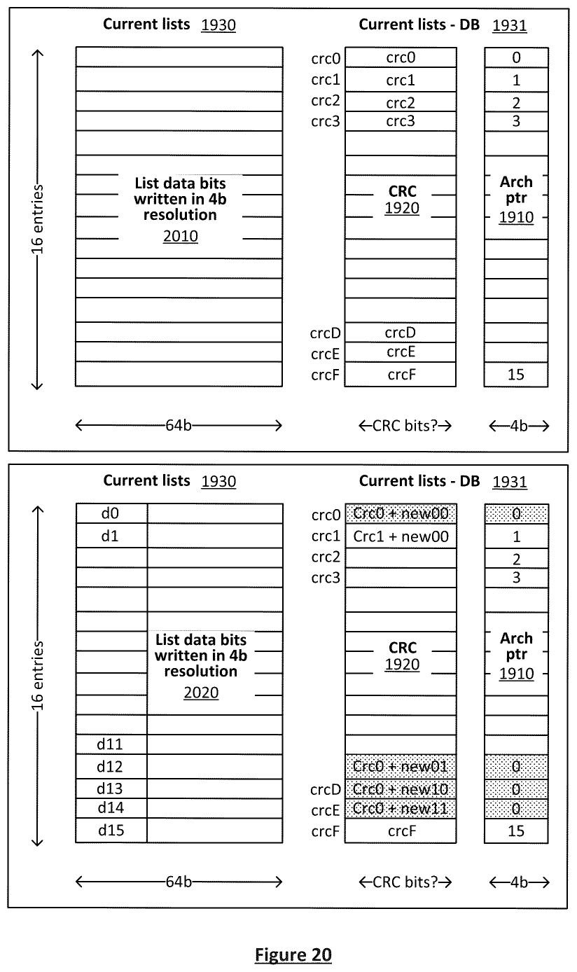

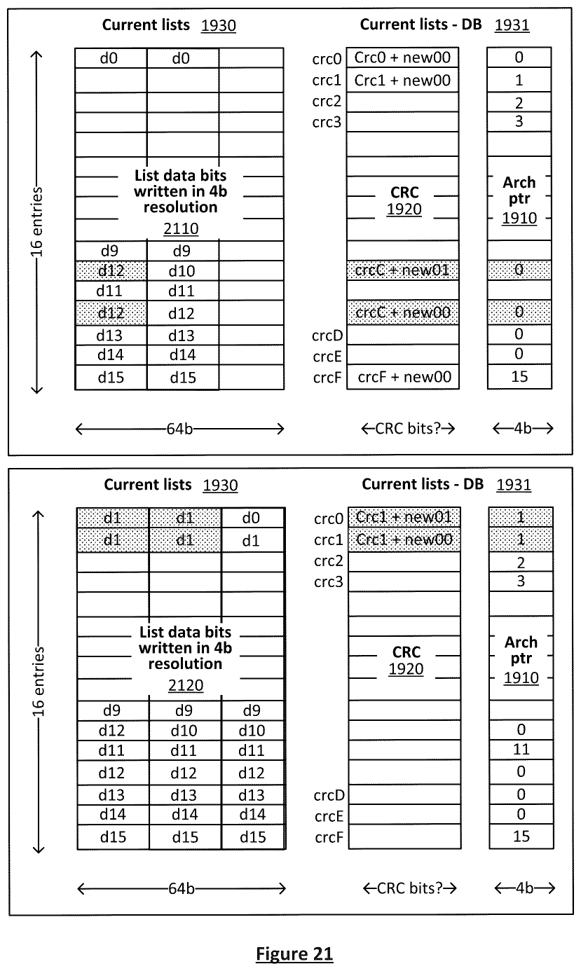

Referring next to FIGS. 20-21, list manager constructs at various stages of a decoding process will be discussed in accordance with various example embodiments. The list manager constructs include the current lists buffer 1930, and a current lists database (DB) 1931. The current lists database 1931 includes the CRC buffer 1920 and the archive list buffers 1940. In the following example embodiment, the current lists buffer 1930 and management of the CRC buffer 1920 are illustrated. Dynamic frozen management is the same as management of the CRC buffer 1920.

First construct states 2010 illustrates the states of the list manager constructs at the start of working on a new allocation of 64 bits. Second construct states 2020 illustrates the states of the list manager constructs after subtree decoding has been completed. At this point, as indicated by the archive pointer buffer 1910, list 0 is cloned 4 times and lists 12, 13 and 14 are removed from consideration.

Third construct states 2110 illustrates the states of the list manager constructs at completion of decoding another sub-tree. As indicated by the first column of the current lists buffer 1930, list 12 is cloned 2 times. As indicated by the archive pointer buffer 1910, list 10 is removed from consideration, and (current) list 12 is copied over list 10.

Fourth construct states 2120 illustrates the states of the list manager constructs at completion of last subtree decoding. At this point, list 1 is cloned 2 times, and list 0 is removed from consideration. Current List 1 is copied over list 0.

At this point, the lists in current lists buffer 1930 are committed to “archive.” Additionally, the current lists database 1931 is copied to the next archive, and past archive sections are copied in one cycle to the correct location according to the pointers. In the illustrated example embodiment, the archive pointers indicate that list 1 will be copied to the location for the list 0, and list 0 will be copied to locations for lists 10, 12, 13, and 14. The remaining lists will be copied to their “usual” location, e.g., list 1 to the location for list 1, list 2 to the location for list 2, etc.

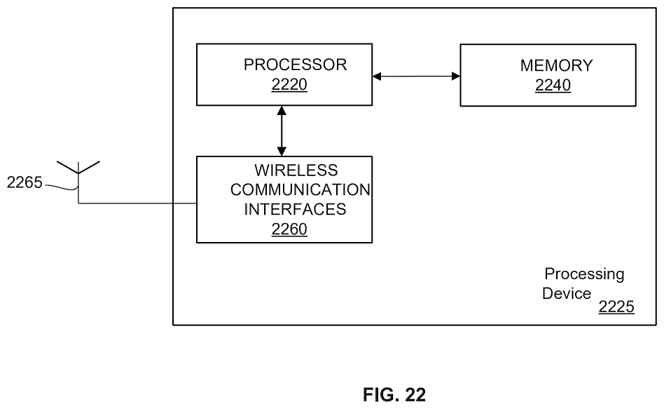

Referring next to FIG. 22, an example embodiment of a processing device 2200 is illustrated in accordance with various example embodiments. As shown, the processing device 2200 includes: a memory 2240; a processor 2220 connected to the memory 2240; various interfaces (e.g., wireless communication interfaces) 2260 connected to the processor 2220; and may optionally include one or more antennas 2265 connected to the various interfaces 2260. The various interfaces 2260 and the antenna 2265 may constitute a transceiver for transmitting/receiving a polar encoded codeword. As will be appreciated, depending on the particular implementation, the processing device 2200 may include many more components than those shown in FIG. 22. However, it is not necessary that all of these generally conventional components be shown in order to disclose the illustrative example embodiments.

The memory 2240 may be a computer readable storage medium that includes a random access memory (RAM), a read only memory (ROM), and/or a permanent mass storage device, such as a disk drive. The memory 2240 may also store an operating system and other routines/modules/applications for providing the functionalities of the processing device 2200 to be executed by the processor 2220. These software components may also be loaded from a separate computer readable storage medium into the memory 2240 using a drive mechanism (not shown). Such separate computer readable storage medium may include a disc, tape, DVD/CD-ROM drive, memory card, or other like computer readable storage medium (not shown). In some example embodiments, software components may be loaded into the memory 2240 via one of the various interfaces 2260, rather than via a computer readable storage medium.

The processor 2220 may be configured to carry out instructions of a computer program by performing the arithmetical, logical, and input/output operations of the system. Instructions may be provided to the processor 2220 by the memory 2240.

The various interfaces 2260 may include components that interface the processor 2220 with the antenna 2265, or other input/output components. As will be understood, the various interfaces 2260 and programs stored in the memory 2240 may be used to achieve one or more special purpose functionalities of the processing device 2200, where those special purpose functionalities will vary depending on the implementation of the processing device 2200. For example, the processing device 2200 may be configured such that the processor executes a program of instructions stored in the memory to implement part or all of a decoder as discussed in various example embodiments, or a device including a decoder.

The various interfaces 2260 may also include one or more user input devices (e.g., a keyboard, a keypad, a mouse, or the like) and user output devices (e.g., a display, a speaker, or the like).

As discussed herein, the terminology “one or more” and “at least one” may be used interchangeably. Furthermore, although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of this disclosure. As used herein, the term “and/or,” includes any and all combinations of one or more of the associated listed items.

When an element is referred to as being “connected,” or “coupled,” to another element, it may be directly connected or coupled to the other element, or more intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, components, and/or groups thereof, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Specific details are provided in the preceding description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures, and techniques may be shown without unnecessary detail in order to avoid obscuring example embodiments.

As discussed herein, illustrative embodiments have been described with reference to acts and symbolic representations of operations (e.g., in the form of flow charts, flow diagrams, data flow diagrams, structure diagrams, block diagrams, etc.) that may be implemented as program modules or functional processes including routines, programs, objects, components, data structures, etc., that perform particular tasks or implement particular abstract data types and may be implemented using existing hardware at, for example, existing user equipment or other network elements and/or hardware. Such existing hardware may be processing or control circuitry such as, but not limited to, one or more processors, one or more Central Processing Units (CPUs), one or more controllers, one or more arithmetic logic units (ALUs), one or more digital signal processors (DSPs), one or more microcomputers, one or more field programmable gate arrays (FPGAs), one or more System-on-Chips (SoCs), one or more programmable logic units (PLUs), one or more microprocessors, one or more Application Specific Integrated Circuits (ASICs), or any other device or devices capable of responding to and executing instructions in a defined manner.

Although a flow chart may describe the operations as a sequential process, many of the operations may be performed in parallel, concurrently, or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling function or the main function.

As disclosed herein, the term “storage medium,” “computer readable storage medium” or “non-transitory computer readable storage medium” may represent one or more devices for storing data, including read only memory (ROM), random access memory (RAM), magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing and/or containing, instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store computer program code, and the at least one memory and the computer program code may be configured to, with at least one processor, cause a network element or network device to perform the necessary tasks. Additionally, the processor, memory, and example algorithms, encoded as computer program code, serve as means for providing or causing performance of operations discussed herein.

A code segment of computer program code may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable technique including memory sharing, message passing, token passing, network transmission, etc.

The terms “including” and/or “having,” as used herein, are defined as comprising (i.e., open language). The term “coupled,” as used herein, is defined as connected, although not necessarily directly, and not necessarily mechanically. Terminology derived from the word “indicating” (e.g., “indicates” and “indication”) is intended to encompass all the various techniques available for communicating or referencing the object/information being indicated. Some, but not all, examples of techniques available for communicating or referencing the object/information being indicated include the conveyance of the object/information being indicated, the conveyance of an identifier of the object/information being indicated, the conveyance of information used to generate the object/information being indicated, the conveyance of some part or portion of the object/information being indicated, the conveyance of some derivation of the object/information being indicated, and the conveyance of some symbol representing the object/information being indicated.

According to example embodiments, user equipment, other network elements, modules, blocks, or the like, may be (or include) hardware, firmware, hardware executing software or any combination thereof. Such hardware may include processing or control circuitry such as, but not limited to, one or more processors, one or more CPUs, one or more controllers, one or more ALUs, one or more DSPs, one or more microcomputers, one or more FPGAs, one or more SoCs, one or more PLUs, one or more microprocessors, one or more ASICs, or any other device or devices capable of responding to and executing instructions in a defined manner.

Benefits, other advantages, and solutions to problems have been described above with regard to specific embodiments of the invention. However, the benefits, advantages, solutions to problems, and any element(s) that may cause or result in such benefits, advantages, or solutions, or cause such benefits, advantages, or solutions to become more pronounced are not to be construed as a critical, required, or essential feature or element of any or all the claims.

1. A decoder comprising:
a memory storing instructions; and
a processor coupled to the memory, the processor configured to execute the instructions to cause the decoder to
receive a polar encoded codeword including frozen bits having arbitrary values,
generate a pruned decoding list tree by collapsing special subtrees identified based on a frozen-qualifiers vector defining values and locations of the frozen bits having arbitrary values within the polar encoded codeword,
perform first soft calculations for nodes in upper layers of the pruned decoding list tree, the first soft calculations generating first outputs including soft values for nodes in the upper layers of the pruned decoding list tree,
perform mid-layer soft calculations for nodes in mid layers of the pruned decoding list tree, the mid-layer soft calculations generating second outputs including a plurality of lists of path metrics for each root node of a subtree of the pruned decoding list tree, each path metric associated with a path from the root node of the subtree to a terminal node of the subtree, the plurality of lists including L lists, each of the L lists including K best path options, the L lists cumulatively including L×*K best path options,
calculate hypotheses and costs for each of K best path options included in each of the L lists according to a size and a type of the pruned decoding list tree, the hypotheses representing decisions for potential decode continuation,
determine the best path out of the L×*K best path options based on the hypotheses and costs of each of the K best path options included in each of the L lists, and a hard decision function, and
output a decoded codeword based on the best path.

2. The decoder of claim 1, wherein:
the special subtrees include at least one of a double parity check (DPC) tree and a double single-parity-check (DSPC) tree; and
the decoder is further caused to decode the at least one of the DPC tree and the DSPC tree by extracting a given number of best candidates from one or more tables based on a set of input conditions related to values of frozen vectors included in the at least one of the DPC tree and the DSPC tree.

3. The decoder of claim 1, wherein the special subtrees include an exhaustive search tree of size 8, and wherein the decoder is further caused to:
generate vectors for each possible codeword for the exhaustive search tree;
calculate a path metric for each possible codeword at the root node of the exhaustive search tree; and
select a specific number of best codewords out of all possible codewords as the specific number of best options for the exhaustive search tree, wherein the specific number of best codewords have the specific number of best path metrics.

4. The decoder of claim 1, wherein the frozen-qualifiers vector defines at least one of the frozen bits as a dynamic frozen bit having a dynamic value dependent upon one or more information bits.

5. The decoder of claim 4, wherein each of at least one of the special subtrees includes a dynamic frozen bit, and the processor is configured to execute the instructions to divide each of the at least one of the special subtrees into smaller subtrees until the one or more information bits on which the dynamic value of the dynamic frozen bit depends are not included in the same subtree as the dynamic frozen bit.

6. The decoder of claim 1, wherein the decoder is further caused to support parallel decoding of a variable number of codewords with a variable number of lists.

7. The decoder of claim 1, wherein the decoder is further caused to concurrently perform first soft calculations for each of three upper layers of the pruned decoding list tree.

8. The decoder of claim 1, wherein the decoder is further caused to concurrently perform mid-layer soft calculations for a plurality of subtrees of the pruned decoding list tree.

9. A method for decoding comprising:
receiving a polar encoded codeword including frozen bits having arbitrary values;
generating a pruned decoding list tree by collapsing special subtrees identified based on a frozen-qualifiers vector defining values and locations of the frozen bits having arbitrary values within the polar encoded codeword;
performing first soft calculations for nodes in upper layers of the pruned decoding list tree, the first soft calculations generating first outputs including soft values for nodes in the upper layers of the pruned decoding list tree;
performing mid-layer soft calculations for nodes in mid layers of the pruned decoding list tree, the mid-layer soft calculations generating second outputs including a plurality of lists of path metrics for each root node of a subtree of the pruned decoding list tree, each path metric associated with a path from the root node of the subtree to a terminal node of the subtree, the plurality of lists including L lists, each of the L lists including K best path options, the L lists cumulatively including L×*K best path options;
calculating hypotheses and costs for each of K best path options included in each of the L lists according to a size and a type of the pruned decoding list tree, the hypotheses representing decisions for potential decode continuation;
determining the best path out of the L×*K best path options based on the hypotheses and costs of each of the K best path options included in each of the L lists, and a hard decision function; and
outputting a decoded codeword based on the best path.

10. The method of claim 9, wherein the special subtrees include at least one of a double parity check (DPC) tree and a double single-parity-check (DSPC) tree, and wherein the method further includes:
decoding the at least one of the DPC tree and the DSPC tree by extracting a given number of best candidates from one or more tables based on a set of input conditions related to values of frozen vectors included in the at least one of the DPC tree and the DSPC tree.

11. The method of claim 9, wherein the special subtrees include an exhaustive search tree of size 8, and wherein the method further comprises:
generating vectors for each possible codeword for the exhaustive search tree;
calculating a path metric for each possible codeword at the root node of the exhaustive search tree; and
selecting a specific number of best codewords out of all possible codewords as the specific number of best options for the exhaustive search tree, wherein the specific number of best codewords have the specific number of best path metrics.

12. The method of claim 9, wherein the frozen-qualifiers vector defines at least one of the frozen bits as a dynamic frozen bit having a dynamic value dependent upon one or more information bits.

13. The method of claim 12, wherein each of at least one of the special subtrees includes a dynamic frozen bit, and the method further comprises:
dividing each of the at least one of the special subtree into smaller subtrees until the one or more information bits on which the dynamic value of the dynamic frozen bit depends are not included in the same subtree as the dynamic frozen bit.

14. The method of claim 9, further comprising:
decoding, in parallel, a variable number of codewords with a variable number of lists.

15. The method of claim 9, further comprising:
performing concurrently the first soft calculations for each of three upper layers of the pruned decoding list tree; and
performing concurrently the mid-layer soft calculations for a plurality of subtrees of the pruned decoding list tree.

16. A decoder comprising:
a memory storing instructions;
a processor coupled to the memory, the processor configured to execute the instructions to cause the decoder to
coordinate operations of a plurality of decoder modules to perform simplified sequential list decoding of a polar encoded codeword including frozen bits having arbitrary values using a controller;
perform soft calculations for target nodes using at least one soft calculation module, the soft calculations being performed on a per target node basis for target nodes of a pruned decoding list tree;
generate a plurality of lists identifying best paths within each subtree of the pruned decoding list tree using a subtree decision module, the plurality of lists including L lists, each of the L lists including K best path options, the L lists cumulatively including L×*K best path options;
select a best list of the L lists using a subtree decision module, the best list including a best path of the L×*K best path options; and
manage the plurality of lists, including the best list, generated by the subtree decision module using a list management module.

17. The decoder of claim 16, wherein the processor is further configured to use the controller to:
maintain decode state variables using node indexes; and
generate the pruned decoding list tree by collapsing special subtrees identified based on a frozen-qualifiers vector defining values and locations of the frozen bits having arbitrary values within the polar encoded codeword.

18. The decoder of claim 16, wherein the decoder is further caused to use the at least one soft calculation module to:
receive first node identifiers from the controller, the polar encoded codeword, and up to L lists including past decisions from the list manager module;
perform first soft calculations for nodes identified by the first node identifiers, the polar encoded codeword, and the up to L lists, wherein performing the first soft calculations includes using a value of 0.5 for each bit of the polar encoded codeword; and
generate first outputs including soft values for nodes in first layers of the pruned decoding list tree.

19. The decoder of claim 16, wherein the decoder is further caused to use the at least one soft calculation module to:
receive second node identifiers from the controller and to receive the polar encoded codeword, the second node identifiers identifying a root node of a subtree of the pruned decoding list tree;
perform second soft calculations for the root node identified by the second node identifiers; and
generate second outputs including lists of path metrics for each of the root node, each path metric associated with a path from the root node of the subtree to a terminal node of the subtree.

20. The decoder of claim 16, wherein the decoder is further caused to use the subtree decision module to:
calculate hypotheses and costs for each of K best path options included in each of the L lists according to a size and a type of the pruned decoding list tree, the hypotheses representing decisions for potential decode continuation;
determine the best path of the L×*K best path options based on the hypotheses and costs of each of the K best path options included in each of the L lists;
calculate hard decisions for the K best path options included in each of the L lists; and
output the hard decision to the list management module.
